(19) United States
(12) Patent Application Publication
(10) Pub. No.: US 2012/0180725 A1
(43) Pub. Date: Jul. 19, 2012

(54) CVD APPARATUS

(75) Inventors: Shinya Yasunaga, Chiyoda-ku (JP); Masakiyo Ikeda, Chiyoda-ku (JP); Hiroshi KIKUCHI, Chiyoda-ku (JP); Noriyasu Sakurai, Chiyoda-ku (JP); Ryusuke Nakasaki, Chiyoda-ku (JP); Jin Liu, Chiyoda-ku (JP); Satoshi Yamano, Chiyoda-ku (JP)

(73) Assignee: FURUKAWA ELECTRIC CO., LTD., Tokyo (JP)

(21) Appl. No.: 13/351,808

(22) Filed: Jan. 17, 2012

(30) Foreign Application Priority Data
Jan. 17, 2011 (JP) 2011-006744
Aug. 23, 2011 (JP) 2011-181632
Jan. 13, 2012 (JP) 2012-005325

(51) Int. Cl. C23C 16/46; C23C 16/54

(52) U.S. Cl. 118/718; 118/725

(57) ABSTRACT

A cold wall type CVD apparatus that can enhance a raw material yield is provided. The CVD apparatus has a raw material gas jetting unit 11 for jetting raw material gas, a susceptor 14 for supporting a tape-shaped base material T and heating the tape-shaped base material T through heat transfer, a heater 15 for heating the susceptor 14, an inert gas introducing unit 12a for introducing inert gas to suppress the contact between the heater and the raw material gas, and a raw material gas transport passage L_{G} for guiding the raw material gas jetted from the raw material gas jetting unit 11 to the surface of the tape-shaped base material.

### CROSS-REFERENCE TO RELATED APPLICATIONS

The present application is based on and claims priority under 35 USC 119 from Japanese Patent Applications No. 2011-006744 filed on Jan. 17, 2011, No. 2011-181632 filed on Aug. 23, 2011 and No. 2012-5325 filed on Jan. 13, 2012. All the contents of these applications on which the claim for priority is based are incorporated herein.

### BACKGROUND OF THE INVENTION

1. Field of the Invention

The present invention relates to a cold wall type (internal-heat type) CVD apparatus for forming superconductive film (or superconductive thin film) on the surface of a tape-shaped base material.

2. Description of the Related Art

RE type superconductors (RE: rare earth) are known as one type of high-temperature superconductors which exhibit superconductivity at the liquid nitrogen temperature (77 K) or more. Particularly, yttrium type oxide superconductors represented by the chemical formula YBa₂Cu₃O_{7-y} (hereinafter referred to as YBCO) is typically known. For example, a chemical vapor deposition method (CVD method: Chemical Vapor Deposition method) for forming a superconductive layer by supplying raw material gas onto the surface of a base material and chemically reacting the raw material gas has been used for formation of this YBCO thin film.

When superconductive wires rods are manufactured by using the CVD method, raw material gas is supplied to the surface of an elongated tape-shaped base material and chemically reacted in a reaction chamber of a CVD apparatus to form a superconductive layer while the tape-shaped base material is made to run at a fixed speed (1 to 100 m/h). For example, when YBCO thin film is formed on a tape-shaped base material, β-di ketone metal complex of each of Y, Ba and Cu is dissolved with tetrahydrofuran (THF) or the like, and raw material gas obtained by mixing and vaporizing predetermined amounts of these solutions is sprayed onto the surface of the tape-shaped base material.

As CVD apparatuses for manufacturing superconductive wire rods as described above are known a hot wall type (external-heat type) in which the whole reaction chamber is heated to heat a tape-shaped base material with radiation heat from the wall body of the reaction chamber, and a cold wall type (internal-heat type) in which a susceptor for supporting a tape-shaped base material is heated to heat the tape-shaped base material with heat transferred from the susceptor (for example, JP-A-2005-256160).

As compared with the cold wall type CVD apparatus, the hot wall type CVD apparatus is lower in maintenance performance and inferior in operation cost and raw material cost. Therefore, the inventors of this application have adopted the cold wall type CVD apparatus to manufacture superconductive wire rods. The cold wall type CVD apparatus is disclosed in FIG. 10 of Patent document 1. The structure described in the Patent Document 1 has a problem that introduced raw material gas (containing O₂) is brought into contact with a heater (formed of SiC) and thus the heater is deteriorated by chemical reactions.

Therefore, the inventors has proposed a CVD apparatus in which a heater is embedded in a bottom wall of a reaction chamber to prevent the raw material gas from coming into contact with the heater (see FIGS. 1 and 2).

As shown in FIGS. 1 and 2, a susceptor 14 for supporting a tape-shaped base material T, a heater 15 for heating the susceptor 14, a first shielding plate 16 for limiting a jetting area of raw material gas in the longitudinal direction, etc. are disposed in a reaction chamber 10C. A raw material gas jetting portion 11 is disposed at the upper wall of the reaction chamber 10C, and an exhaust portion 13 is disposed at the bottom wall of the reaction chamber 10. An opening portion 12 is formed in the bottom wall of the reaction chamber 100, and the susceptor 14 and the heater 15 are mounted in the opening portion 12.

Here, it is required to keep the susceptor 14 at 700° C. to 800° C. when a superconductive layer is formed on a tape-shaped base material. However, when the bottom wall of the reaction chamber 10C and the susceptor 14 come into close contact with each other, it is difficult to keep the temperature of the susceptor 14 high because of heat transfer. Therefore, the susceptor 14 is disposed so as to be spaced from the bottom wall of the reaction chamber 100 through a predetermined gap 12a. When the raw material gas flows from the gap 12a into the installation space of the heater 15, the heater 15 is deteriorated. Therefore, inert gas is introduced into the reaction chamber 100 by using the gap 12a as an inert gas introducing port (counter flow).

In the reaction chamber 100 shown in FIGS. 1 and 2, the inside of the reaction chamber 10c is set under a high-temperature and low-pressure state, and thus raw material gas jetted from the raw material gas jetting portion 11 comes into contact with the inert gas introduced from the gap 12a before the raw material gas concerned reaches the tape-shaped base material T, so that an engulfing phenomenon of the inert gas occurs. When the inert gas is engulfed, the raw material gas is diffused and thus the concentration of the raw material gas is lowered, so that the amount of the raw material gas which contributes to film formation on the tape-shaped base material T is lowered and thus the yield of the raw material is lowered.

### SUMMARY OF THE INVENTION

The present invention has been implemented to solve the foregoing problem, and has an object to provide a CVD apparatus that can enhance the yield of a raw material.

According to the present invention, there is provided a CVD apparatus comprising: a raw material gas jetting portion that jets raw material gas; a susceptor that supports a tape-shaped base material and heats the tape-shaped base material through heat transfer; a heater that heats the susceptor; an inert gas introducing portion that introduces inert gas to suppress contact between the heater and the raw material gas, and a raw material transport passage that guides the raw material gas jetted from the raw material gas jetting portion to the surface of the tape-shaped base material.

In this construction, the raw material gas transport passage may be disposed so as to be spaced from the susceptor at a predetermined interval. Or, the raw material gas transport passage may have an opening end narrower than the width of the susceptor, and the raw material gas transport passage may be disposed along a running area of the tape-shaped base material formed at the center in the width direction of the susceptor.

The interval distance between the raw material gas transport passage and the susceptor may be smaller than the width of the opening end of the raw material gas transport passage. The reaction chamber may be provided with a temperature controller that controls the temperature of raw material gas passing through the raw material gas transport passage.

The susceptor may be provided with a support portion that supports the tape-shaped base material, and dummy tapes may be disposed at both the sides of the support portion. The raw material gas transport passage may be disposed so as to be spaced from the susceptor at a predetermined interval, and the tip of a passage wall of the raw material gas transport passage may be disposed so as to face an area within the width of the dummy tapes.

Furthermore, the dummy tapes may be disposed so as to protrude from the end portions of the passage wall of the raw material gas transport passage to the opposite side to the tape-shaped base material in the width direction of the dummy tapes. Still furthermore, the dummy tapes may be disposed so as to be spaced from both the edge portions in the width direction of the tape-shaped base material at predetermined intervals. Still furthermore, the tape-shaped base material may be suspended between and wound around a pair of reels, and the dummy tapes may be suspended between and wound around a pair of dummy tape reels disposed at the outside of the reels in the suspending and winding direction of the tape-shaped base material.

The susceptor may be provided with lower portions that are lower in height than the support portion and located at both the sides of the support portion for supporting the tape-shaped base material so as to face tips of the passage wall of the raw material gas transport passage. Furthermore, the lower portions may be configured to be wider than the thickness of the tips of the passage wall of the raw material gas transport passage.

Furthermore, the susceptor may have a pair of groove portions extending along the tape-shaped base material at both the sides of the support portion, and the lower portions may contain at least bottom surfaces of the groove portions. Low temperature members that are lower in temperature than the susceptor may be arranged at the lower portions.

Still furthermore, the low temperature members may be formed of material that is smaller in thermal conductivity than material constituting the susceptor. The height positions of the surfaces of the low temperature members are set to be lower than the height position of the surface of the tape-shaped base material supported on the support portion.

Still furthermore, the susceptor may be provided with low temperature portions that are lower in temperature than the support portion and located at both the sides of the support portion for supporting the tape-shaped base material so as to face tips of the passage wall of the raw material gas passage. Low temperature members that are lower in temperature than the susceptor may be arranged at the low temperature portions.

The low temperature members may be formed of material which is smaller in thermal conductivity than material constituting the susceptor. The height positions of the surfaces of the low temperature members may be set to be lower than the height position of the surface of the tape-shaped base material supported on the support portion.

According to the present invention, the inert gas which is introduced into the reaction chamber to prevent deterioration of the heater can be suppressed from being engulfed by the raw material gas, and thus the raw material yield when the superconductive layer is formed on the tape-shaped base material can be remarkably enhanced.

### BRIEF DESCRIPTION OF THE DRAWINGS

FIG. 1 is a plan view showing the internal structure of a reaction chamber constituting a conventional cold wall type CVD apparatus;

FIG. 2 is a diagram showing a cross-section of A-A of FIG. 1;

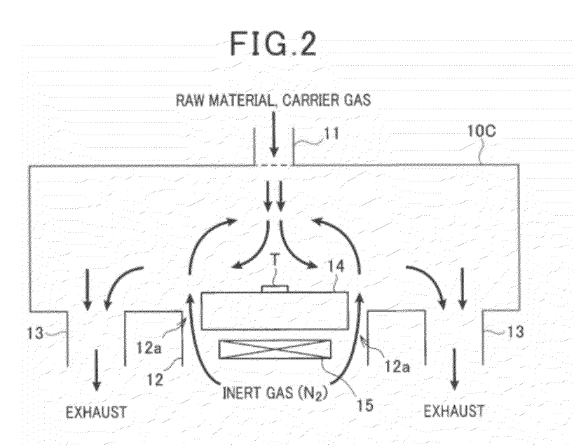

FIG. 3 is a diagram showing the construction of a CVD apparatus according to a first embodiment;

FIG. 4 is a plan view showing the internal construction of a reaction chamber constituting the CVD apparatus;

FIG. 5 is a diagram showing a cross-section of B-B of FIG. 4;

FIG. 6 is a plan view showing the internal construction of a reaction chamber according to a modification 1;

FIG. 7 is a plan view showing the internal construction of a reaction chamber according to a modification 2;

FIG. 8 is a diagram showing the construction of a CVD apparatus according to a second embodiment;

FIG. 9 is a plan view showing the arrangement construction of the tape-shaped base material and dummy tapes;

FIG. 10 is a perspective view showing the construction of the dummy tapes;

FIG. 11 is a side cross-sectional view showing the internal construction of a growth chamber;

FIG. 12 is a diagram showing a cross-section of C-C of FIG. 11;

FIG. 13 is a graph showing the relationship of a growth time, the amount of deposited material and a critical current characteristic;

FIG. 14 is a diagram showing the construction of a CVD apparatus according to a third embodiment;

FIG. 15 is a plan view showing the arrangement construction of a tape-shaped base material and dummy tapes;

FIG. 16 is a laterally cross-sectional view showing the internal construction of a growth chamber;

FIG. 17 is a diagram showing the construction of a CVD apparatus according to a fourth embodiment;

FIG. 18 is a plan view showing the arrangement construction of a tape-shaped base material;

FIG. 19 is a side cross-sectional view showing the internal structure of a growth chamber;

FIG. 20 is a diagram showing a cross-section of D-D of FIG. 19;

FIG. 21 is a partially enlarged cross-sectional view of FIG. 20;

FIG. 22 is a partially enlarged cross-sectional view showing a lower portion formed on a susceptor according to a modification 3;

FIG. 23 is a partially enlarged cross-sectional view showing a lower portion formed on a susceptor according to a modification 4;

FIG. 24 is a partially enlarged cross-sectional view showing the internal construction of a growth chamber according to a fifth embodiment;

FIG. 25 is a partially enlarged cross-sectional view showing a lower portion formed on a susceptor according to a modification 5;

FIG. 26 is a partially enlarged cross-sectional view showing a lower portion formed on a susceptor according to a modification 6;

FIG. 27 is a partially enlarged cross-sectional view showing a lower portion formed on a susceptor according to a modification 7; and

FIG. 28 is a partially enlarged cross-sectional view showing the internal construction of a growth chamber according to a sixth embodiment.

### DETAILED DESCRIPTION OF PREFERRED EMBODIMENTS

Embodiments according to the present invention will be described hereunder with reference to the drawings.

### First Embodiment

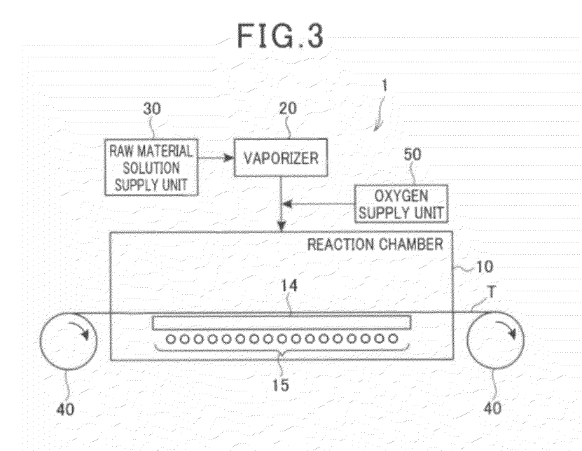

FIG. 3 is a diagram showing the construction of a CVD apparatus according to a first embodiment. As shown in FIG. 3, a CVD apparatus 1 is configured to have a base material feeding unit 40 for making a tape-shaped base material T run while winding up the tape-shaped base material T, a raw material solution supply unit 30 for supplying raw material for superconductive film (or superconductive thin film), a vaporizer 20 for vaporizing the raw material solution and supplying the raw material to the reaction chamber 10, a reaction chamber 10 for forming thin film on the surface of the tape-shaped base material T, etc.

The raw material solution supply unit 30 mixes predetermined amounts of raw material solutions for the thin film to be formed on the surface of the tape-shaped base material T (for example, solutions obtained by dissolving diketone metal complexes of Y, Ba and Cu as raw materials for YBCO in a proper amount of tetrahydrofuran (THF)) and supplies the mixed raw material solution to the vaporizer 20.

The vaporizer 20 sprays the raw material solution supplied from the raw material solution supply unit 30 together with carrier gas (for example, argon Ar) and heats the raw material solution to vaporize the raw material solution. Thereafter, the vaporized raw material gas is mixed with oxygen (O₂) supplied from an oxygen supply unit 50, and then supplied to the reaction chamber 10.

The base material feeding unit 40 is configured to reciprocally feed the tape-shaped base material T, and it feeds the tape-shaped base material T at a predetermined speed in the reaction chamber 10.

The tape-shaped base material T has a tape-like shape having a width of about 10 mm, and it has an intermediate layer which is used to form film on a metal substrate by biaxially orienting crystal grains of superconductor, for example.

In the reaction chamber 10, the raw material gas supplied from the vaporizer 20 is jetted to the tape-shaped base material T running in the reaction chamber 10 and chemically reacted, whereby superconductive layer film is formed on the surface of the tape-shaped base material. The reaction chamber 10 contains a susceptor 14 for supporting the tape-shaped base material T and heating the tape-shaped base material T through heat transfer, and a heater 15 for heating the susceptor 14. That is, the CVD apparatus 1 is a cold wall type CVD apparatus.

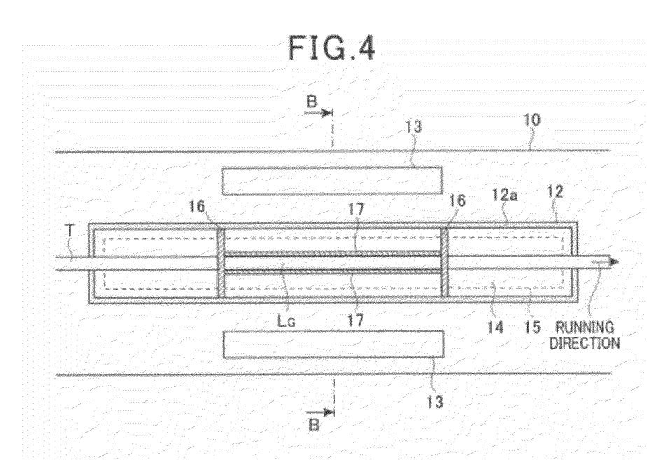

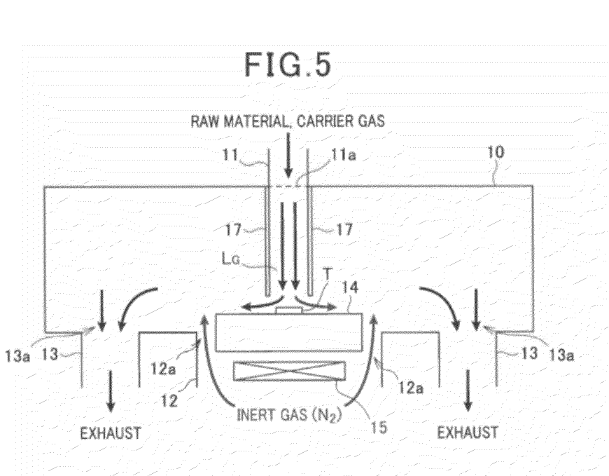

FIG. 4 is a plan view showing the internal construction of the reaction chamber 10, and FIG. 5 is a diagram showing a B-B cross-section of FIG. 4. The reaction chamber 10 is assumed to be a laterally long rectangular parallelepiped, and the short-side direction of the reaction chamber 10 (the direction perpendicular to the running direction of the tape-shaped base material T) is referred to as width direction.

As shown in FIGS. 4 and 5, an opening portion 12 extending in the running direction of the tape-shaped base material T (the longitudinal direction of the reaction chamber 10) is formed in the bottom wall of the reaction chamber 10, and the susceptor 14 is disposed in the opening portion 12. The susceptor 14 is a heat-transfer plate which supports the running tape-shaped base material T and heats the tape-shaped base material T through heat transfer. An area at the center in the width direction of the susceptor 14 serves as a running area of the tape-shaped base material T.

The susceptor 14 is disposed so that the peripheral edge portion thereof is spaced from the bottom wall of the reaction chamber 10 through a predetermined gap 12a. When a superconductive layer is formed on the tape-shaped base material T, it is necessary to hold the susceptor 14 at 700 to 800° C. However, when the bottom wall of the reaction chamber 10 and the susceptor 14 come into close contact with each other, heat transfer makes it difficult to hold the susceptor 14 at high temperature.

A heater 15 (for example, a ceramic heater formed of SiC) which is one-size smaller than the susceptor 14 is disposed just below the susceptor 14. The susceptor 14 is heated to a predetermined temperature by the heater 15, whereby the surface of the tape-shaped base material T is kept to a proper temperature (the film formation temperature of the superconductive layer).

Inert gas (for example, N₂) is introduced from the gap 12a between the bottom wall of the reaction chamber 10 and the susceptor 14. The inert gas is introduced to prevent the raw material gas from flowing into an installation space of the heater 15 from the gap 12a and deteriorating the heater 15. That is, the reaction chamber 10 has an inert gas introducing portion using the gap 12a as an introducing port.

A raw material gas jetting portion 11 is disposed at the upper wall of the reaction chamber 10. The raw material gas jetting portion 11 has a rectangular raw material gas jetting port 11a formed along the longitudinal direction at the center in the width direction of the upper wall of the reaction chamber 10. A mesh plate having many fine pores (for examples, φ 1.5 mm) formed therein is disposed at the raw material gas jetting port 11a, and the raw material gas and the carrier gas are jetted from the fine ports of the mesh plate at a predetermined jetting speed. When a superconductive layer is formed on the tape-shaped base material T, the jetting speed of the raw material gas is set to 10 m/s or more.

Rectangular first shielding plates 16 having substantially the same width as the susceptor 14 are vertically suspended at both the ends in the longitudinal direction of the raw material gas jetting port 11a on the upper wall of the reaction chamber 10. The first shielding members 16 have heat resistance to the film formation temperature for forming a superconductive layer, and are formed of material which does not react with the raw material gas (for example, SUS). The first shielding plates 16 are disposed so as to be spaced from the upper surface of the susceptor 14 (the running face of the tape-shaped base material T) at a predetermined interval to enable the tape-shape base material T to run.

A superconductive layer is formed on the tape-shaped base material T in an area (film formation area) sandwiched between the two first shielding plates 16. That is, diffusion of the raw material gas in the longitudinal direction is suppressed by the first shielding plates 16, whereby an excellent superconductive layer is formed in the film formation area.

Tunnel-like cut-out portions may be formed at the lower end portions of the first shielding plates 16 so that the tape-shaped base material T passes through the cut-out portions. Furthermore, shielding gas (for example, argon Ar) may be jetted downwardly from the lower end faces of the first shielding plates 16 or along the first shielding plates 16 to form a gas curtain at the boundary between the film formation area and a film non-formation area (pre-heating area).

Exhaust portions 13 having exhaust ports 13a whose lengths correspond to the film formation area are disposed at both the sides in the width direction of the susceptor 14 in the bottom wall of the reaction chamber 10. The exhaust portions 13 have an exhaust pump (not shown) and exhaust unreacted raw material gas, carrier gas, etc. to the outside of the reaction chamber 10.

Furthermore, in this embodiment, rectangular second shielding plates 17 having substantially the same width as the length of the film formation area (corresponding to the arrangement interval between the first shielding plates 16) are vertically suspended along the longitudinal direction at both the sides in the width direction of the raw material gas jetting port 11a on the upper wall of the reaction chamber 10. The second shielding plates 17 have heat resistance to the film formation temperature for forming a superconductive layer and also are formed of material which does not react with the raw material gas (for example, SUS) as in the case of the first shielding plates 16. In order to exhaust the raw material gas, etc. to the exhausting portions 13, the second shielding plates 17 are disposed so as to be spaced from the upper face of the susceptor 14 at a predetermined interval.

Furthermore, both the ends of the second shielding plates 17 are joined to the first shielding plates 16, thereby forming a raw material gas transport passage L_{G}. That is, the raw material gas jetted from the raw material gas jetting portion 11 is guided to the surface of the tape-shaped base material T by the raw material gas transport passage L_{G}.

As described above, the reaction chamber 10 has the raw material gas jetting portion 11 for jetting raw material gas at a predetermined jetting speed, the susceptor 14 for supporting the tape-shaped base material T and heating the tape-shaped base material T through heat transfer, and the heater 15 for heating the susceptor 14. The reaction chamber 10 further has the inert gas introducing portion (the inert gas introducing port) 12a for introducing inert gas into the reaction chamber 10 in order to prevent flow-in of raw material gas into the installation space of the heater 15. Furthermore, the raw material gas transport passage L_{G} for guiding raw material gas to the surface of the tape-shaped base material T from the raw material gas jetting portion 11 is provided.

Specifically, the susceptor 14 is disposed along the longitudinal direction of the reaction chamber, the heater 15 is disposed just below the susceptor 14, and the introducing port (gap 12a) of the inert gas introducing portion is formed along both the side edge portions in the width direction of the susceptor 14. The raw material gas transport passage L_{G} has an opening end narrower than the width of the susceptor 14, and is disposed along the running area of the tape-shaped base material T which is formed at the center in the width direction of the susceptor 14.

The raw material gas is transported to the neighborhood of the tape-shaped base material T through the raw material gas transport passage L_{G} formed by the first shielding plates 16 and the second shielding plates 17, so that the raw material gas hardly comes into contact with the inert gas introduced from the gap 12a (inert gas introducing portion) until it reaches the tape-shaped base material T. That is, the inert gas introduced into the reaction chamber 10 to prevent deterioration of the heater 15 can be suppressed from being engulfed by the raw material gas, so that the yield of the raw material when superconductive layer film is formed on the tape-shaped base material T can be remarkably increased.

Here, the gap distance between the raw material gas transport passage L_{G} and the susceptor 14, particularly the gap distance between the second shielding plate 17 and the susceptor 14 is desired to be smaller than the width of the opening end of the raw material gas transport L_{G} (corresponding to the arrangement interval of the second shielding plates 17).

Accordingly, the exhaust speed of the raw material gas from the raw material gas transport passage L_{G} increases, so that the inert gas is further suppressed from being engulfed by the raw material gas and thus the raw material yield can be increased.

### Example 1

In an example 1, the distance from the raw material gas jetting port 11a to the susceptor 14 was set to 60 mm, the gap distance between the second shielding plate 17 and the susceptor 14 was set to 30 mm, and the width of the opening end of the raw material gas transport passage L_{G} was set to 18 mm in the film forming apparatus shown in FIG. 5. A superconductive layer which was formed of YBa₂Cu₃O_{7-y} and had a thickness of 1 μm was formed on a metal substrate tape having 0.1 mm thickness and containing an intermediate layer by this film forming apparatus. The reaction temperature was set to 770° C., and the reaction pressure was set to 10 Torr.

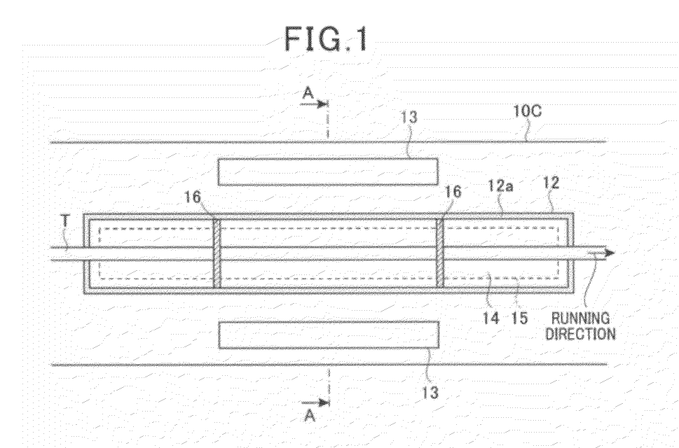

Furthermore, as a comparison example 1, a YBCO layer was formed as in the case of the example 1 by using a film forming apparatus having no second shielding plate 17 (see FIG. 1).

As shown in the following table 1, the manufacturing speed of the superconductive layer of 1 μm thickness, that is, the raw material yield is more greatly improved in the example 1 as compared with the comparative example 1.

TABLE 1

| | COMPARATIVE | | |
|---|---|---|---|
| | EXAMPLE 1 | EXAMPLE 1 | |
| GAP DISTANCE BETWEEN | NO SECOND | 30 | mm |
| SECOND SHIELDING PLATE | SHIELDING | | |
| 17 AND SUSCEPTOR 14 | PLATE | | |
| TEMPERATURE | NO | NO | |
| CONTROLLER | | | |
| MANUFACTURING SPEED OF | 1.1 m/h | 1.5 | m/h |
| SUPERCONDUCTIVE LAYER | | | |
| OF 1 μm THICKNESS | | | |

When the raw material gas transport passage L_{G} is excessively close to the susceptor 14, the raw material gas transport passage L_{G} is more easily heated by radiation heat from the susceptor 14. In this case, the raw material gas passing through the raw material gas transport passage L_{G} may react before it reaches the tape-shaped base material T, and this causes reduction in raw material yield. Therefore, it is desirable that the gap distance between the raw material gas transport passage L_{G} and the susceptor 14 is not less than 4 mm.

### [Modification 1]

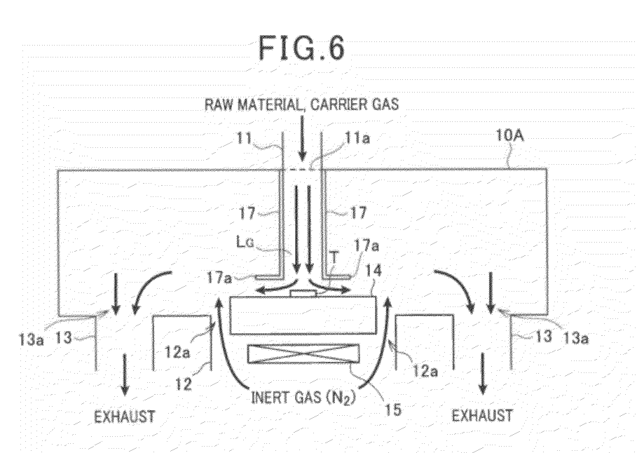

FIG. 6 is a plan view showing the internal construction of a reaction chamber 10A according to a modification 1.

The construction of the reaction chamber 10A shown in FIG. 6 is substantially identical to the reaction chamber 10 of the embodiment, and thus the description on the duplicative parts are omitted. In the reaction chamber 10A, the same constituent elements as the reaction chamber 10 of the embodiment are represented by the same reference numerals.

As shown in FIG. 6, a flange 17a is formed at the opening end of the raw material gas transport passage L_{G} in the reaction chamber 10A so as to extend outwardly in the width direction in parallel to the upper surface of the susceptor 14. The tip of the flange 17a is located to be nearer to the center side in the width direction than the side edge portion of the susceptor (the end portion of the gap 12a serving as the inert gas introducing port). This is because the inert gas would easily flow into the raw material gas transport passage L_{G} if the tip of the flange 17a reaches and covers the gap 12a.

As described above, by forming the flange 17a at the opening end of the raw material gas transport passage L_{G}, the inert gas can be efficiently suppressed from being entangled by the raw material gas, so that the raw material yield can be further increased.

For example, when the length of the flange 17a is set to 10 mm or more and the tip of the flange 17a is located at the center side in the width direction so as to be spaced from the side edge portion of the susceptor 14 at a distance of 10 mm or more, the raw material yield can be more remarkably increased.

### [Modification 2]

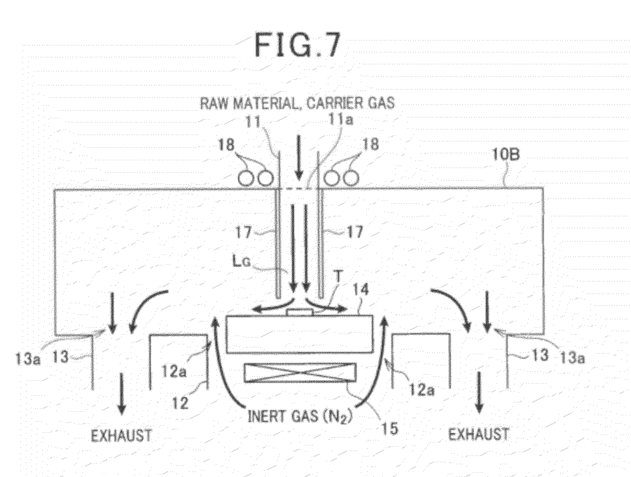

FIG. 7 is a plan view showing the internal construction of a reaction chamber 10B according to a modification 2.

The construction of the reaction chamber 10B shown in FIG. 7 is substantially the same as the reaction chamber 10 of the embodiment, and thus the description on the duplicative parts is omitted. In the reaction chamber 10B, the same constituent elements as the reaction chamber 10 of the above embodiment are represented by the same reference numerals.

As shown in FIG. 7, in the reaction chamber 10B, a temperature controller 18 for controlling the temperature of raw material gas passing through the raw material gas transport passage L_{G} is disposed in the neighborhood of the raw material gas jetting portion 11. The neighborhood of the raw material gas jetting portion 11 is a peripheral edge area of the raw material gas jetting port 11a on the upper wall of the reaction chamber 10B, for example. The temperature controller 18 is suitably based on a method of circulating cooling oil or cooling water through the inside of the reaction chamber structuring body or a cooling medium pipe disposed in the neighborhood of the raw material gas jetting portion 11. Furthermore, there is an effective method of circulating cooling oil through the inside of the second shielding plates 17 or a cooling medium pipe which is brought into contact with the second shielding plates 17.

### Example 2

In an example 2, in the film forming apparatus shown in FIG. 7, cooling oil of the temperature controller 18 was introduced at 70° C., and a YBCO layer was formed as in the case of the example 1. The film forming apparatus was the same as in the case of the example 1, containing the dimension, except that the temperature controller 18 was provided. Furthermore, the gap distance between the second shielding plate 17 and the susceptor 14 was set to 8 mm, and an effect of the gap distance was also investigated.

TABLE 2

| | EXAMPLE 2-1 | | EXAMPLE 2-2 | |
|---|---|---|---|---|
| GAP DISTANCE BETWEEN | 30 | mm | 8 | mm |
| SECOND SHIELDING PLATE | | | | |
| 17 AND SUSCEPTOR 14 | | | | |
| TEMPERATURE | exist | | exist | |
| CONTROLLER | | | | |
| MANUFACTURING SPEED OF | 1.7 | m/h | 2.2 | m/h |
| SUPERCONDUCTIVE LAYER | | | | |
| OF 1 μm THICKNESS | | | | |

As shown in the table 2, the manufacturing speed, that is, the raw material yield for the 1 μm thickness is slightly improved in the example 2-1 as compared with the example 1. Furthermore, adherence of raw material to the raw material gas transport passage L_{g} side of the second shielding plates 12 was observed in the example 1, however, no adherence of raw material was observed in the example 2-1.

Furthermore, in the example 2-2, the manufacturing speed (raw material yield) of the superconductor layer of 1 μm thickness was remarkably increased by setting the gap distance from the susceptor 14 to 8 mm. As described above, the raw material yield can be more greatly enhanced by providing the temperature controller 18 and reducing the gap distance from the susceptor 14.

When the raw material gas transport passage L_{G} is disposed as in the case of the embodiment, the raw material gas transport passage L_{G} (the first shielding plates 16 and the second shielding plates 17) is heated by radiation heat from the susceptor 14. Therefore, the raw material gas passing through the raw material gas transport passage L_{G} reacts before it reaches the tape-shaped base material T, and thus there occurs a disadvantage that clogging occurs at the raw material gas jetting port 11a whose temperature increases or the like.

In the reaction chamber 10B of the modification 2, the raw material gas can be held to a proper temperature (for example, 300° C.) by the temperature controller 18, and thus it can be effectively suppressed that the internal temperature of the raw material gas transport passage L_{G} increases and thus the raw material gas reacts.

In the reaction chamber 10B of the modification 2, the flange 17a may be provided to the opening end of the raw material gas transport passage L_{G} as in the case of the modification 1.

Here, the arrangement of the susceptor 14 and the heater 15 in the reaction chamber 10 is not limited to this embodiment. That is, the present invention is applicable to a CVD apparatus which is configured so that the susceptor and the heater are disposed in the reaction chamber insofar as this structure allows inert gas to be introduced into the reaction chamber in order to prevent the contact of raw material gas to the heater.

Furthermore, in this embodiment, the raw material gas transport passage L_{G} is constructed by the first shielding plates 16 and the second shielding plates 17, however, the raw material gas transport passage L_{G} may be constructed by one tubular member having a rectangular cross-section.

### Second Embodiment

In the above construction, unreacted raw material gas which does not contribute to film formation is decomposed and crystallized above the susceptor at the outside of the tape-shaped base material T in the width direction, and deposits on the susceptor to form deposit (abnormal growth layer). This deposit is easily formed at a narrow portion in the gap between the raw material gas transport passage (hereinafter referred to as an extension nozzle) and the susceptor. As the film formation time elapses, the deposit concerned trends to enlarge and disturb flow of exhaust gas to be exhausted from the extension nozzle through the gap to the outside.

Furthermore, the deposit may intrude onto the tape-shaped base material T, and thus disturb film formation in the neighborhood of the edge portions in the width direction of the tape-shaped base material T or induce abnormal growth of a superconductive layer on the surface of the tape-shaped base material T.

Therefore, when the film formation of the superconductor layer is carried out for a long time, the enlargement of the deposit induces occurrence of crystal abnormality of the superconductive layer on the surface of the tape-shaped base material T, and thus there may occur a problem that the superconductivity characteristic of manufactured superconductive wire rods degrades.

Therefore, in the CVD apparatus according to the second embodiment, it is an object to enhance the raw material yield and perform stable film formation of a superconductive layer on the surface of the tape-shaped base material T.

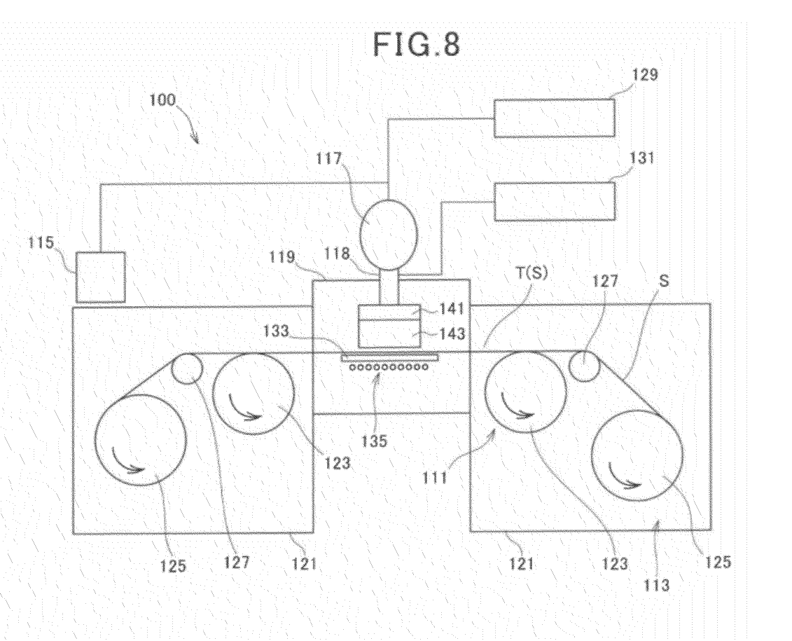

FIG. 8 is a diagram showing the construction of a CVD apparatus 100 according to a second embodiment. As shown in FIG. 8, the CVD apparatus 100 has a base material feeding unit 111 for winding up an elongated tape-shaped superconductive base material (hereinafter referred to as tape-shaped base material T) while making the take-shaped base material T run, a dummy tape feeding unit 113 for winding up elongated dummy tapes (deposit avoiding units) S disposed at both the sides in the width direction of the tape-shaped base material T while making the dummy tapes s run, a raw material solution supply unit 115 for supplying raw material for superconductive film, a vaporizer 117 for vaporizing raw material solution, and a growth chamber (reaction chamber) 119 into which the vaporized raw material gas, the tape-shaped base material T and the dummy tapes S are supplied to form thin film on the surface of the tape-shaped based material T. Reel chambers 121 are connected to the growth chamber 119, and a closed space through which the tape-shaped base material T and the dummy tapes S run is formed in the growth chamber 119 and the reel chambers 121.

The raw material solution supply unit 115 mixes predetermined amounts of raw material solutions for the thin film to be formed on the surface of the tape-shaped base material T (for example, solutions obtained by dissolving diketone metal complexes of Y, Ba and Cu as raw materials for YBCO in a proper amount of tetrahydrofuran (THF)) and supplies the mixed raw material solution to the vaporizer 117.

The vaporizer 117 sprays and heats the raw material solution supplied from the raw material supply unit 115 together with carrier gas (for example, argon Ar) supplied from the carrier gas supply unit 129 to vaporize the raw material solution. The vaporized raw material gas is mixed with oxygen (O₂) supplied from the oxygen supply unit 131 and then supplied to the growth chamber 119.

The base material feeding unit 111 has a pair of reels 123 for the base material between which the tape-shaped substrate T is suspended while the tape-shaped base material T is wound around the reels, and feeds the tape-shaped base material T at a predetermined speed (1 to 100 m/h) in the growth chamber 119. The base material reels 123 are disposed in the reel chambers 121 respectively, and driven to be rotatably forwardly and reversely. In this embodiment, the tape-shaped base material T is reciprocally fed in the growth chamber 119 in which the raw material gas is supplied, whereby a superconductive layer of a predetermined film thickness (for example, 0.5 μm to 3 μm) can be efficiently formed on the surface of the tape-shaped base material T. Thereafter, a stabilizing layer is formed on the superconductive layer of the tape-shaped base material T having the superconductive layer formed thereon by a sputtering device, thereby manufacturing a superconductive wire rod.

The tape-shaped base material T has a tape-shape of about 10 mm in width, and it has an intermediate layer on a metal substrate of 100 μm in thickness. As the material of the metal substrate may be used metal such as Mo, Ta, Ag, Cu, Fe, Nb, Ni, W, Mn, Cr or the like or alloy thereof, which is excellent in strength and heat resistance. The intermediate layer is used to perform film formation by biaxially orienting crystal grains of superconductor.

The tape-shaped base material T may be formed by using a non-oriented metal substrate having low magnetism and forming a monolayer or multilayer biaxially-oriented intermediate layer on the non-oriented metal substrate with a sputtering device using ion beam assist called as IBAD (Ion Beam assisted Deposition) method. Plural intermediate layers may be further formed on the biaxially-oriented intermediate layer by using the sputtering device or a PLD (Pulse Laser Deposition) device.

Furthermore, the tape-shape base material T may be formed by using an oriented metal substrate which is formed of nickel (Ni) alloy and biaxially oriented simultaneously with removal of surface oxide film by an orientation heat treatment under a reducing ambient and forming an intermediate layer on the oriented metal substrate.

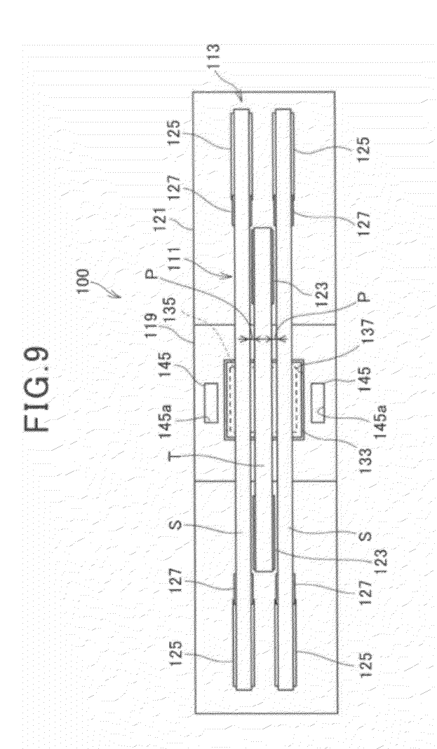

The dummy tape feeding unit 113 has a pair of dummy tape reels 125 between and around which each dummy tape S is suspended and wound, and support reels 127 disposed between the dummy tape reels 125, and feeds the dummy tapes S at a predetermined speed equal to or less than the running speed of the tape-shaped base material T in the growth chamber 119. In this construction, the dummy tapes S are disposed at both the sides in the width direction of the tape-shaped base material T as shown in FIG. 9, and the dummy tape reels 125 and the support reels 127 are juxtaposed with each other so as to sandwich the reels 123 for the base material in the reel chambers 121.

The dummy tape reels 125 are configured to be rotated in one direction, and feed the dummy tapes S from the one dummy tape reels 125 to the other dummy tape reels 125. Accordingly, the raw material gas is crystallized, and deposits deposited on the dummy tapes S are wound up by the dummy tape reels 125 together with the dummy tapes S, whereby the deposits can be efficiently discharged to the outside of the growth chamber 119. The dummy tape reels 125 are disposed at the outside of the base material reels 123 with respect to the suspending and winding direction of the tape-shaped base material T. Here, the suspending and winding direction of the tape-shaped base material T means the longitudinal direction of the tape-shaped base material T which is suspended between and wound around the base material reels 123. According to this construction, the deposits deposited on the dummy tape S and the dummy tape S are wound up by the dummy tape reels 125 at the outside of the area where the tape-shaped base material T is fed. Therefore, even when the deposits drop from the dummy tapes S during the wind-up operation, the dropping deposits does not intrude into the feeding area of the tape-shaped base material T, and thus the quality of the tape-shaped base material T can be secured.

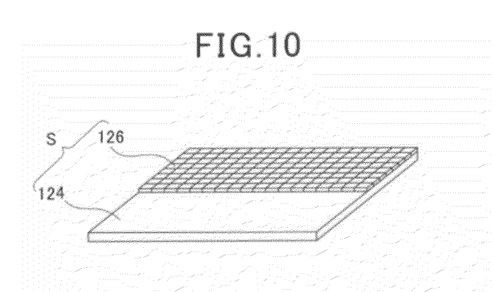

The dummy tapes S are formed of materials having at least substantially the same level heat resistance as the tape-shaped base material T. In this embodiment, as shown in FIG. 10, a material similar to the tape-shaped material T, specifically, a material having a metal substrate 124 constituting the tape-shaped base material T and an intermediate layer 126 formed on the metal substrate 124 is used as the dummy tapes S. According to this construction, when the superconductive layer is formed on the tape-shaped base material T, the dummy tapes S do not have any adverse effect on the tape-shaped base material T which is caused by the difference in surface state and the difference in radiation, and thus raw material gas which has been crystallized can be easily deposited on the surfaces of the dummy tapes S. In this embodiment, the material having only the intermediate layer 126 on the metal substrate 124 is used as the dummy tape S, however, the dummy tape S is not limited to this material. A material having a metal substrate 124, an intermediate layer 126 and a superconductive layer (not shown) formed on the intermediate layer 126, or materials having only the metal substrate 124 may be used as the dummy tapes S. According to this construction, for example, materials which fail in the manufacturing process may be used as the dummy tapes S, and thus the material cost can be reduced.

Furthermore, the dummy tapes S are disposed so as to be spaced from both the edge portions of the tape-shaped base material T in the width direction thereof at a predetermined interval P as shown in FIG. 9. There is a case where the tape-shaped base material T and the dummy tapes S run while swinging (meandering) in the width direction. In this case, when the tape-shaped base material T and the dummy tapes S come into contact with each other, it may affect the film formation quality of the surface of the tape-shaped base material T. Therefore, the predetermined interval P is set to a value larger than an expected swinging amount in the width direction (1 to 2 mm in this embodiment).

In the growth chamber 119, raw material gas supplied from the vaporizer 117 is jetted to the tape-shaped base material running in the growth chamber 119 to be chemically reacted, thereby forming a superconductive layer on the surface of the tape-shaped base material T. Furthermore, as shown in FIG. 8, the growth chamber 119 contains a susceptor 133 for supporting the tape-shaped base material T and the dummy tapes S and heating them through heat transfer, and a heater 135 for heating the susceptor 133. That is, the CVD apparatus 100 is a cold wall type CVD apparatus.

Next, the internal construction of the growth chamber 119 will be described.

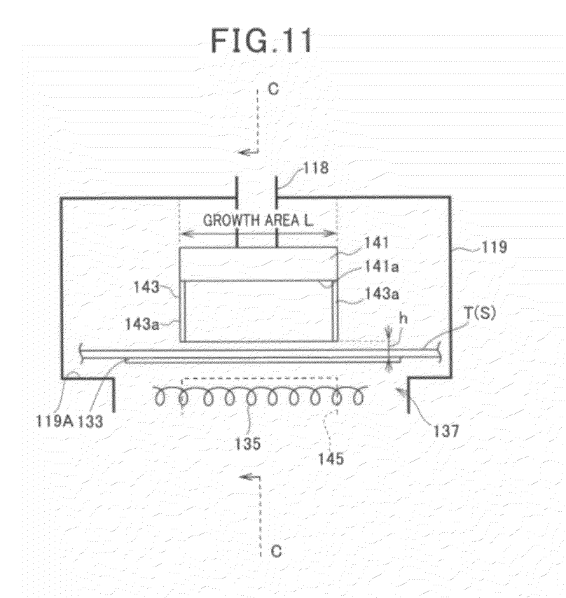

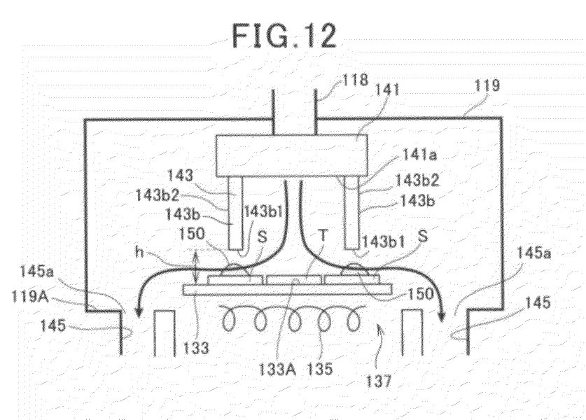

FIG. 11 is a side cross-sectional view showing the internal construction of the growth chamber 119, and FIG. 12 is a diagram showing a C-C cross-section of FIG. 11. The growth chamber 119 is assumed to have a laterally long rectangular parallelepiped, and the short-side direction of the growth chamber 119 (the direction perpendicular to the running direction of the tape-shaped base material T and the dummy tapes S) is referred to as the width direction.

As shown in FIGS. 11 and 12, an opening portion 137 is formed in the bottom wall 119A of the growth chamber 119, and the susceptor 133 is disposed in the opening portion 137. The susceptor 133 is a heat transfer plate for supporting the running tape-shaped base material T and dummy tapes S and also heating the tape-shaped base material T and the dummy tapes S through heat transfer. An area at the center in the width direction of the susceptor 133 serves as a running area of the tape-shaped base material T and the dummy tapes S.

In this embodiment, the susceptor 133 has a support portion 133A for supporting the running tape-shaped base material T, and the dummy tapes S run at both the sides of the support portion 133A in the width direction thereof.

As shown in FIG. 12, the susceptor 133 is disposed so that the peripheral edge portion thereof is spaced from the bottom wall 119A of the growth chamber 119 at a predetermined interval. When a superconductive layer is formed on the tape-shaped base material T, it is necessary to keep the susceptor 133 at 700 to 800° C. However, when the bottom wall 119A of the growth chamber 119 and the susceptor 133 are in contact with each other, it is difficult to keep the susceptor 133 at high temperature because of heat transfer from the susceptor 133 to the bottom wall 119A.

A heater (for example, a ceramic heater formed of SiC) which is one-size smaller than the susceptor 133 is disposed just below the susceptor 133. The susceptor 133 is heated to a predetermined temperature by the heater 135, whereby the surface of the tape-shaped base material T is kept to a proper temperature (the film formation temperature of the superconductive layer).

A raw material gas jetting unit 141 which is connected to the vaporizer 117 (FIG. 8) through a connection pipe 118 is disposed at the upper portion of the growth chamber 119. The raw material gas jetting unit 141 has a rectangular raw material gas jetting port 141a formed at the center in the width direction of the upper wall of the growth chamber 119. A mesh plate having many fine pores (for example, φ1.5 mm) formed therein is disposed at the raw material gas jetting port 141a, and raw material gas and carrier gas are jetted from the fine pores of the mesh plate at a predetermined jetting speed. When a superconductive layer is formed on the tape-shaped base material T, the jetting speed of the raw material gas is set to 10 m/s or more.

Furthermore, an extension nozzle (raw material gas transport passage) 143 for guiding raw material gas jetted from the raw material gas jetting port 141a to the surface of the tape-shaped base material T is provided to the raw material gas jetting unit 141. This extension nozzle 143 has first shielding plates 143a disposed along the width direction of the tape-shape base material T so as to face each other, and second shielding plates 143b disposed along the running direction of the tape-shaped base material T so as to face each other, and it is designed in a rectangular tubular shape. The first shielding plates 143a and the second shielding plates 143b have heat resistance to the film forming temperature for forming a superconductive layer, and also formed of materials (for example, SUS) which are unreacted with the raw material gas.

According to this construction, the extension nozzle 143 for guiding the raw material gas jetted from the raw material gas jetting port 141a to the surface of the tape-shaped base material T is provided, whereby the amount of raw material gas contributing to the film formation on the tape-shaped base material T can be increased, and thus the raw material yield can be increased. Furthermore, according to this construction, as shown in FIG. 11, the superconductive layer is formed on the tape-shaped base material T in a growth area (film forming area) L sandwiched between the two first shielding plates 143a of the extension nozzle 143. That is, an excellent superconductive layer can be formed in the growth area L by suppressing the diffusion in the longitudinal direction of the raw material gas with the first shielding plates 143a.

Furthermore, exhausting portions 145 having exhaust ports 145a whose lengths correspond to the growth area L are disposed at both the sides of the susceptor 133 in the width direction thereof in the bottom wall 119A of the growth chamber 119. The exhausting portions 145 are equipped with an exhaust pump (not shown) to exhaust unreacted raw material gas, carrier gas, etc. to the outside of the growth chamber 119.

As shown in FIGS. 11 and 12, the extension nozzle 143 is disposed so as to be spaced from the upper surface of the susceptor 133 (the surface on which the tape-shaped base material T is disposed) at a predetermined interval h. As described above, the extension nozzle 143 guides the raw material gas jetted from the raw material gas jetting port 141a to the surface of the tape-shaped base material T to increase the amount of the raw material gas contributing to the film formation on the tape-shaped base material T, thereby increasing the raw material yield. Accordingly, it is desired from the viewpoint of increasing the raw material yield that the predetermined interval h is set to a small value to the extent that it does not disturb running of the tape-shaped base material T. However, when the predetermined interval h is excessively small (the extension nozzle 143 and the susceptor 133 excessively approach to each other), the extension nozzle 143 is liable to be heated by radiation heat from the susceptor 133. In this case, raw material gas passing through the extension nozzle 143 may react at a portion heated by radiation heat before it reaches the tape-shaped base material T, which causes reduction in raw material yield. Therefore, it is desirable that the predetermined interval h between the extension nozzle 143 and the susceptor 133 is set to 10 mm or less.

The raw material gas flowing in the extension nozzle 143 is mainly exhausted to the exhausting portions 145 through the predetermined interval h between the second shielding plates 143b and the susceptor 133. It has been found in this construction that unreacted raw material gas which does not contribute to the film formation is crystallized on the susceptor 133 at the outside of the tape-shaped base material T in the width direction thereof and deposits (abnormal growth layer) deposited on the susceptor 133 are formed.

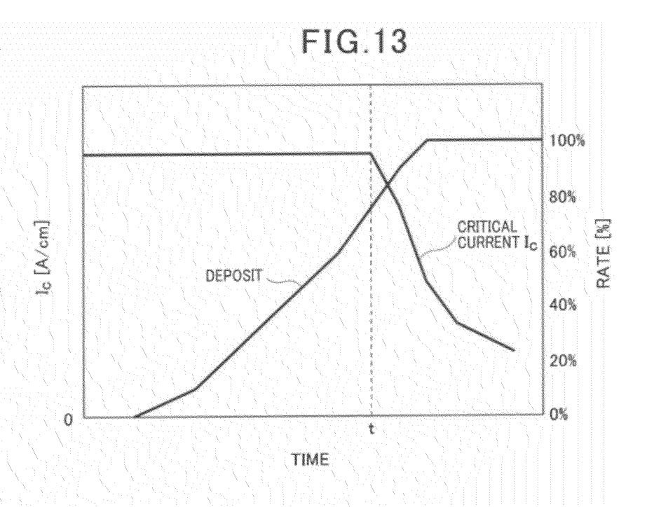

It has been found that this deposit trends to grow as the time elapses, and thus as the ratio of the height of the deposit to the predetermined interval h between the extension nozzle 143 and the susceptor 133 increases, the value of the critical current value Ic of a manufactured superconductive wire rod greatly decreases as shown in FIG. 13, so that the superconductivity characteristic is deteriorated.

Therefore, in this construction, the dummy tapes S are arranged at both the sides in the width direction of the tape-shaped base material T, so that deposits are formed on the dummy tapes S and the deposits deposited are discharged from the growth chamber 119 while the dummy tapes S are made to run.

As shown in FIG. 12, the dummy tapes S are arranged just below the second shielding plates (passage wall) of the extension nozzle 143. It has been experimentally found that raw material gas is liable to be decomposed and deposited in the areas just below the second shielding plates 143b when the raw material gas passes therethrough because these areas are the narrowest portions in the passage through which raw material flows. Therefore, according to this construction, the lower end portions (tips) 143b1 of the second shielding plates 143b of the extension nozzle 143 are located just above the dummy tapes S (so as to face the areas within the width of the dummy tapes S), whereby deposits 150 can be formed on the dummy tapes S and thus the deposits 150 can be easily discharged from the growth chamber 119.

Furthermore, in this construction, the dummy tapes S are disposed so as to protrude from the outer surfaces 143b2 (end portions) of the second shielding plates 143b to the opposite side to the tape-shaped base material T by a predetermined distance (3 mm in this embodiment). According to this construction, when raw material gas flows from the inside of the extension nozzle 143 to the exhausting portions 145, the deposits 150 which are formed at the outside of the outer surfaces 143b2 of the second shielding plates 143b can be also deposited on the dummy tapes S.

Next, the running speed of the dummy tapes S will be described.

The deposits on the dummy tapes S trend to grow as the time elapses. Therefore, as shown in FIG. 13, when the ratio of the height of the deposits 150 to the predetermined interval h between the extension nozzle 143 and the susceptor 133 exceeds a threshold value, the deposits 150 are also deposited not only on the dummy tapes S, but also on the tape-shaped base material T, so that the critical current value Ic of the manufactured superconductive wire rod decreases greatly.

A time t at which the critical current value Ic decreases varies dependently on the supply rate of the raw material gas or the predetermined interval h. Therefore, in this embodiment, the time t at which the critical current value Ic decreases is measured from a film forming condition for the superconductive layer on a trial basis, and the running speed of the dummy tapes S is set so that the total time for which the dummy tapes S stay in the growth area L (FIG. 11) is shorter than the time t. In this case, when the running speed is set to a value near to the lower limit value, an unstable factor increases, and thus a value obtained by multiplying the time t by a predetermined safety rate (for example, 0.9) may be used.

Here, when the running speed of the dummy tapes S is increased, the amount of deposits can be reduced, however, the using amount of the dummy tapes S increases. Therefore, the running speed of the dummy tapes S is set to be equal to or more than the running speed at which the total time for which the dummy tapes S stay in the growth area L is shorter than the time t and also set to the running speed of the tape-shaped base material T or less.

The dummy tapes S may continuously run at the running speed set on the basis of the time t described above, or the dummy tapes S may be stopped in the growth area L and then made to run so that new sites of the dummy tapes S stay in the growth area L before the time t elapses.

### Third Embodiment

Next, a CVD apparatus according to a third embodiment will be described.

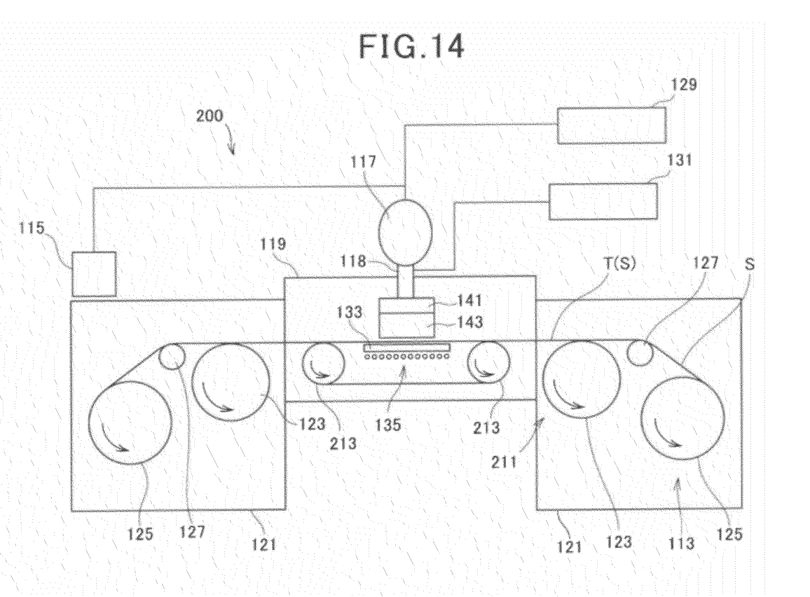

FIG. 14 is a diagram showing the construction of a CVD apparatus 200 according to a third embodiment. The same constituent elements as the CVD apparatus 100 according to the first embodiment described above are represented by the same reference numerals, and the description thereof is omitted.

The CVD apparatus 200 of this embodiment has a base material feeding unit 211 for making the tape-shaped base material T run while winding up the tape-shaped base material T, and the base material feeding unit 211 has a pair of base material reels 123 around which the tape-shaped base material T is wound up while suspended therebetween, and turn reels 213 disposed between the base material reels 123. The turn reels 213 are used to turning the tape-shaped base material T at plural times in the growth chamber 119, so that a long film formation time can be secured in one running operation. Therefore, this embodiment makes film formation of a superconductive layer easier as compared with an apparatus for performing plural film formation treatments.

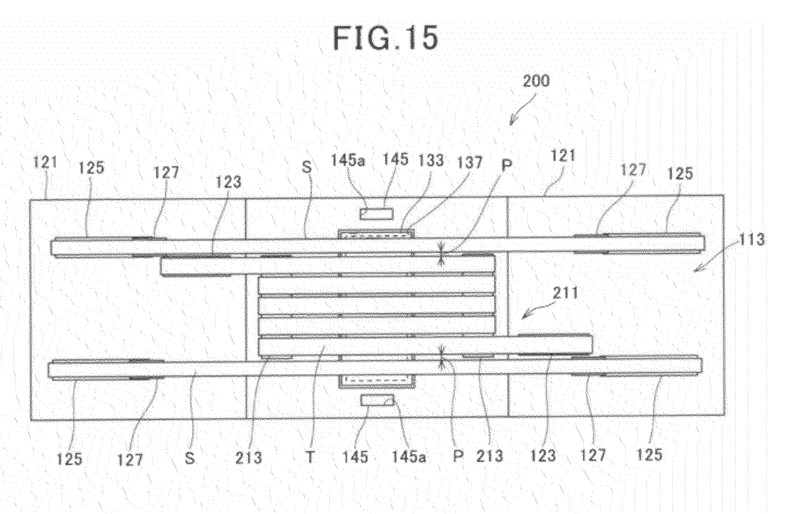

Furthermore, as shown in FIG. 15, even in the case of the multi-turn system of the tape-shaped based material T, the dummy tapes S are arranged so as to be spaced from both the outer edge portions of the tape-shaped base material t at a predetermined interval P.

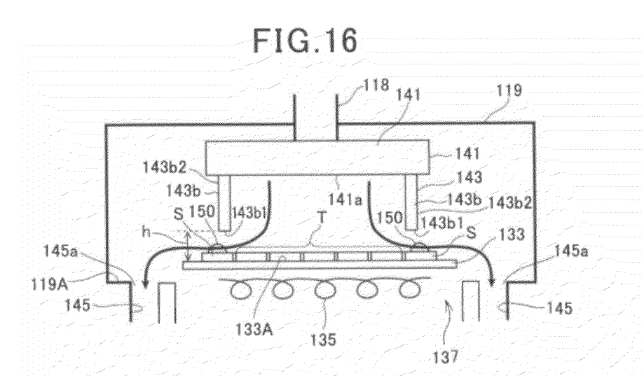

In this third embodiment, the tape-shaped base material T turns around at plural times, whereby the distance between the second shielding plates 143b of the extension nozzle 143 is increased as shown in FIG. 16. Even in this case, the dummy tapes S are arranged just below the second shielding plates 143b of the extension nozzle 143. Therefore, deposits can be formed on the dummy tapes S, and thus the deposits can be easily discharged from the growth chamber 119.

Furthermore, in the third embodiment, the dummy tapes S are arranged so as to protrude from the outer surfaces 143b2 (end portions) of the second shielding plates 143b to the opposite side to the tape-shape base material T by a predetermined distance (3 mm in this embodiment). Therefore, raw material gas flows from the inside of the extension nozzle 143 to the exhaust portions 145, whereby deposits formed at the outside of the outer surfaces 143b2 of the second shielding plates 143b can be also deposited on the dummy tapes S.

As described above, this embodiment has the raw material gas jetting unit 141 for jetting raw material gas, the susceptor 133 for supporting the tape-shaped base material T and heating the tape-shaped base material T through heat transfer, the heater 135 for heating the susceptor 133, and the extension nozzle 143 for guiding the raw material gas guided from the raw material gas jetting unit 141 to the surface of the tape-shaped base material T, and the dummy tapes S are arranged at both the sides in the width direction of the tape-shaped base material T, whereby the deposits deposited on the dummy tapes S can be discharged by making the dummy tapes S run. Accordingly, the deposits can be prevented from disturbing the film formation of the superconductive layer, and the film formation of the superconductive layer on the surface of the tape-shaped base material T can be stably performed.

Furthermore, according to this embodiment, the extension nozzle 143 is disposed so as to be spaced from the upper surface of the susceptor 133 at a predetermined interval h, and the lower end portions 143b1 of the second shielding plates 143b of the extension nozzle 143 are located just above the dummy tapes S, so that deposits formed by decomposition of the raw material gas can be formed on the dummy tapes S and thus the deposits can be easily discharged from the growth chamber 119.

Furthermore, according to this embodiment, the dummy tapes S are disposed so as to protrude from the outer surfaces 143b2 of the second shielding plates 143b of the extension nozzle 143 to the opposite side to the tape-shaped base material T in the width direction of the dummy tapes S. Therefore, when raw material gas flows from the inside of the extension nozzle 143 to the exhaust portions 145, deposits formed at the outside of the outer surface 143b2 of the second shielding plates 143b can be deposited on the dummy tapes S.

Still furthermore, according to this embodiment, the dummy tapes S are arranged so as to be spaced from both the edge portions in the width direction of the tape-shaped base material T at a predetermined interval P. Therefore, the contact between the dummy tapes S and the tape-shaped base material T can be prevented, and the quality of the superconductive layer formed on the surface of the tape-shaped base material T can be enhanced.

Still furthermore, according to this embodiment, the dummy tape S has the metal substrate 124 and the intermediate layer 126 formed on the metal substrate 124. Therefore, when the superconductive layer is formed on the tape-shaped base material T, the dummy tape S does not have any effect on the tape-shaped base material T due to the difference in surface state and the difference in radiation, and crystallized materials of raw material gas can be easily deposited on the surface of the dummy tapes S.

Still furthermore, according to this embodiment, the dummy tapes S run at the running speed of the tape-shaped base material T or less, so that the using amount of the dummy tapes S can be reduced and thus the material cost can be suppressed.

Still furthermore, according to this embodiment, the tape-shaped base material T is suspended between and wound around the pair of base material reels 123, and the dummy tapes S are suspended between and wound around the pair of dummy tape reels 125 arranged at the outside of the base material reels 123 in the suspending and winding direction of the tape-shaped base material T. Therefore, the tape-shaped base material T and the dummy tapes S can be individually made to run, the superconductive film can be formed on the surface of the tape-shaped base material T, and also deposits deposited at both the sides of the tape-shaped base material T can be easily discharged. Furthermore, the deposits deposited on the dummy tape S and the dummy tape S are wound up by the dummy tape reels 125 at the outside of the area in which the tape-shaped base material T is fed. Therefore, even when the deposits drop from the dummy tapes S during the wind-up operation, the dropping deposits does not intrude into the feeding area of the tape-shaped base material T, and the quality of the tape-shaped base material T can be secured.

The present invention is specifically described on the basis of the embodiment. However, the present invention is not limited to the above embodiment, and it may be modified without departing from the subject matter of the present invention.

For example, in the above embodiment, the dummy tapes S are made to run in the growth chamber 119 by the dummy tape feeding unit 113, however, the present invention is not limited to this style insofar as the dummy tapes S on which the deposits are deposited are removed.

Furthermore, in this embodiment, the tape-shaped base material T and the dummy tapes S are made to run on the susceptor 133, and the lower end portions 143b1 of the second shielding plates 143b of the extension nozzle 143 are arranged just above (over) the dummy tapes S. However, the present invention is not limited to this style. When the tips of the second shielding plates 143b of the extension nozzle 143 are located so as to face the area within the width of the dummy tapes S, the tape-shaped base material T and the dummy tapes S may be made to run on the lower surface of the susceptor 133, and the upper end portions of the second shielding plates of the extension nozzle may be arranged just below the dummy tapes S.

Furthermore, in the third embodiment, the CVD apparatus 200 using the multi-turn system of the tape-shaped base material T is described, and the turn reels 213 for turning the tape-shaped base material T are arranged in the growth chamber 119. However, the present invention is not limited to this style, and the turn reels may be arranged in the reel chambers 121.

According to this construction, all the reels are arranged in the reel chambers 121, and thus a maintenance work for each reel, etc. can be easily performed. Furthermore, the growth chamber 119 can be configured in a compact size, and the flow of the raw material gas can be stabilized. In connection with this, it can be expected to stably manufacture the superconductive film.

### Fourth Embodiment

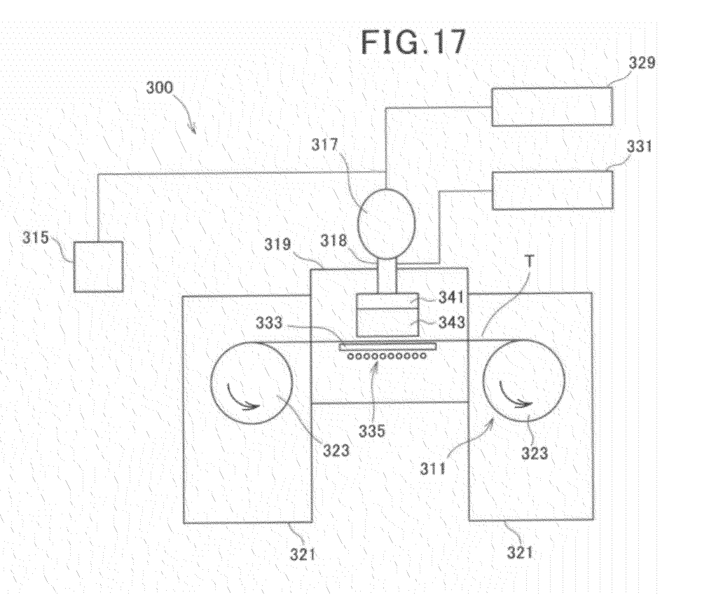

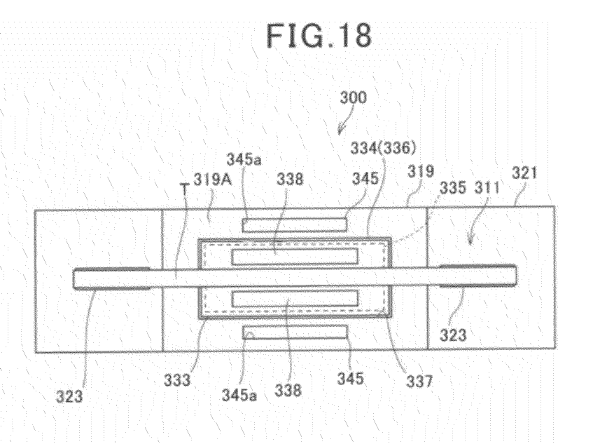

FIG. 17 is a diagram showing the construction of a CVD apparatus 300 according to a fourth embodiment, and FIG. 18 is a plan view showing the arrangement construction of a tape-shaped base material T.

As shown in FIG. 17, the CVD apparatus 300 is configured to have a base material feeding unit 311 for winding up an elongated tape-shaped base material for superconductor (hereinafter referred to as tape-shaped base material T) while making the tape-shaped base material T run, a raw material solution supply unit 315 for supplying raw material for superconductive film, a vaporizer 317 for vaporizing raw material solution, and a growth chamber (reaction chamber) 319 which is supplied with vaporized raw material gas and the tape-shaped base material T to form thin film on the surface of the tape-shaped base material T. Reel chambers 321 are connected to the growth chamber 319, and a closed space in which the tape-shaped base material T runs is formed in the growth chamber 319 and the reel chambers 321.

The raw material solution supply unit 315 mixes predetermined amounts of raw material solutions for the thin film to be formed on the surface of the tape-shaped base material T (for example, solutions obtained by dissolving diketone metal complexes of Y, Ba and Cu as raw materials for YBCO in a proper amount of tetrahydrofuran (THF)) and supplies the mixed raw material solution to the vaporizer 317.

The vaporizer 317 sprays the raw material solution supplied from the raw material solution supply unit 315 together with carrier gas (for example, argon Ar) supplied from a carrier gas supply portion 329 and heats the raw material solution to vaporize the raw material solution. The vaporized raw material gas is mixed with oxygen (O₂) supplied from an oxygen supply unit 331, and then supplied to the reaction chamber 319.

The base material feeding unit 311 has a pair of base material reels 323 between and around which the tape-shaped base material T is suspended and wound, and feeds the tape-shaped base material T at a predetermined speed (1 to 100 m/h) in the growth chamber 319. The base material reels 323 are disposed in the respective reel chambers 321, and rotatable forwardly and reversely. In this embodiment, the tape-shaped base material T is reciprocally fed in the growth chamber 319 in which the raw material gas is supplied, whereby a superconductive layer having a predetermined film thickness (for example, 0.5 μm to 3 μm) can be efficiently formed on the surface of the tape-shaped base material T. Thereafter, a stabilizing layer is formed on the superconductive layer of the tape-shaped base material T having the superconductive layer formed thereon by a sputtering device, thereby manufacturing a superconductive wire rod.

A material which has a tape-like shape of about 10 mm in width and has an intermediate layer formed on a metal substrate of 100 μm in thickness is used as the tape-shaped base material T. As the material of the metal substrate may be used metal such as Mo, Ta, Ag, Cu, Fe, Nb, Ni, W, Mn, Cr or the like or alloy thereof, which is excellent in strength and heat resistance, for example. The intermediate layer is used to perform film formation by biaxially orienting crystal grains of superconductor.

The tape-shaped base material T may be formed by using a non-oriented metal substrate having low magnetism and forming a monolayer or multilayer biaxially-oriented intermediate layer on the non-oriented metal substrate with a sputtering device using ion beam assist called as IBAD (Ion Beam assisted Deposition) method. Plural intermediate layers may be further formed on the biaxially-oriented intermediate layer by using the sputtering device or a PLD (Pulse Laser Deposition) device.

Furthermore, the tape-shape base material T may be formed by using an oriented metal substrate which is formed of nickel (Ni) alloy and biaxially oriented simultaneously with removal of surface oxide film by an orientation heat treatment under a reducing ambient and forming an intermediate layer on the oriented metal substrate.

In the growth chamber 319, raw material gas supplied from the vaporizer 317 is jetted to the tape-shaped base material T running in the growth chamber 319 and chemically reacted, whereby a superconductive layer is formed on the surface of the tape-shaped base material T. Furthermore, as shown in FIG. 18, the growth chamber 319 has a metal (for example, SUS; stainless steel) susceptor 333 for supporting the tape-shaped base material T and heating the tape-shaped base material T through heat transfer and a heater 335 for heating the susceptor 333. That is, the CVD apparatus 300 is a cold wall type CVD apparatus.

Next, the internal construction of the growth chamber 319 will be described.

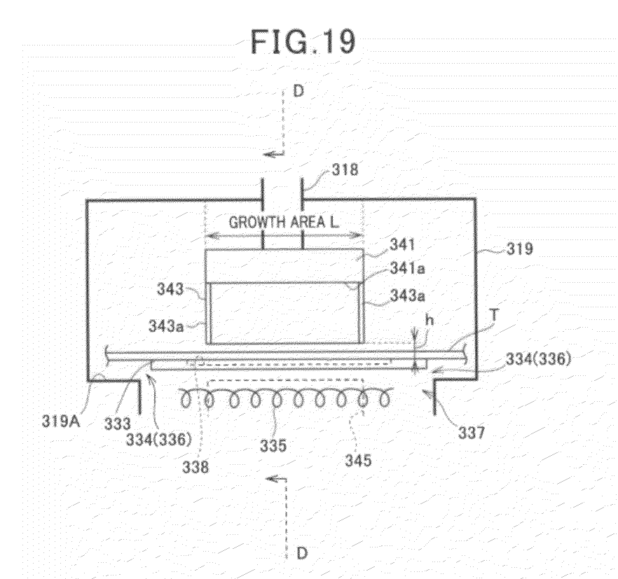

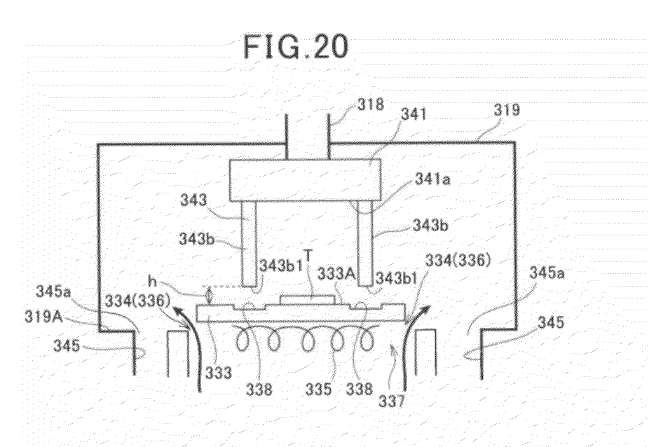

FIG. 19 is a side cross-sectional view showing the internal construction of the growth chamber 319, and FIG. 20 is a diagram of a D-D cross-section of FIG. 19. The growth chamber 319 is assumed to have a laterally long rectangular parallelepiped, and the short-side direction of the growth chamber 319 (the direction perpendicular to the running direction of the tape-shaped base material T) is referred to as the width direction.

As shown in FIGS. 19 and 20, an opening portion 337 is formed in the bottom wall 319A of the growth chamber 319, and the susceptor 333 is disposed in the opening portion 337. As shown in FIG. 20, the susceptor 333 is a heat transfer plate which has a support portion 333A for supporting running tape-shaped base material T and heats the tape-shaped base material T located on the support portion 333A through heat transfer. The support portion 333A is formed substantially at the center in the width direction of the susceptor 333, and the area corresponding to the support portion 333A serves as a running area of the tape-shaped base material T.

As shown in FIGS. 19 and 20, the susceptor 333 is disposed so that the peripheral edge portion thereof is spaced from the bottom wall 319A of the growth chamber 319 at a predetermined interval 334. When a superconductive layer is formed on the tape-shaped base material T, the susceptor 333 is required to be kept to 700 to 800° C. This is because it is difficult to keep the susceptor 333 to high temperature because of heat transfer from the susceptor 333 to the bottom wall 319A when the bottom wall 319A of the growth chamber 319 and the susceptor 333 are in close contact with each other.

A heater (a ceramic heater of SiC, for example) which is one-size smaller than the susceptor 333 is disposed just below the susceptor 333. The susceptor 333 is heated to a predetermined temperature by the heater 335, whereby the surface of the tape-shaped base material T is kept to a proper temperature (the film formation temperature of the superconductive layer).

Furthermore, inert gas (for example, N₂) is introduced from the gap 334 between the bottom wall 319A of the growth chamber 319 and the susceptor 333. The inert gas is introduced to prevent that raw material gas flows into the installation space of the heater 335 from the gap 334 and the heater 335 is deteriorated. That is, the growth chamber 319 has an inert gas introducing portion 336 (FIG. 20) using the gap 334 as an introducing port.

A raw material gas jetting unit 341 which is connected to the vaporizer (FIG. 17) through a connection tube 318 is disposed at the upper portion of the growth chamber 319. The raw material gas jetting unit 341 has a rectangular raw material gas jetting port 341a formed at the center in the width direction of the upper wall of the growth chamber 319. A mesh plate having many fine pores (for example, φ1.5 mm) formed therein is disposed on the raw material gas jetting port 341a, and raw material gas and carrier gas are jetted at a predetermined jetting speed from the fine pores of the mesh plate. When a superconductive layer is formed on the tape-shaped base material T, the jetting speed of the raw material gas is set to 10 m/s or more.

Furthermore, the raw material gas jetting unit 341 is provided with an extension nozzle (raw material gas transport passage) 343 for guiding raw material gas jetted from the raw material gas jetting port 341a to the surface of the tape-shaped base material. The extension nozzle 343 is configured in a rectangular tubular shape so as to have first shielding plates 343a arranged along the width direction of the tape-shaped base material so as to face each other and second shielding plates 343b arranged along the running direction of the tape-shaped base material T so as to face each other. The first shielding plates 343a and the second shielding plates 343b have heat resistance to the film formation temperature for forming the superconductive layer, and they are formed of materials which are not reacted with the raw material gas.

As described above, in this construction, the amount of raw material gas contributing to the film formation of the tape-shaped base material T can be increased by providing the extension nozzle 343 for guiding the raw material gas jetted from the raw material gas jetting port 341a to the surface of the tape-shaped base material T, so that the raw material yield can be enhanced. Furthermore, according to this construction, as shown in FIG. 19, the superconductive layer is formed on the tape-shaped base material Tin the growth area L sandwiched between the two first shielding plates 343a of the extension nozzle 343. That is, the diffusion in the longitudinal direction of the raw material gas can be suppressed by the first shielding plates 343a, whereby an excellent superconductive layer can be formed in the growth area L.

Exhausting portions 345 having exhausting ports 345a whose lengths correspond to the growth area L are arranged at both the sides in the width direction of the susceptor 333 in the bottom wall 319A of the growth chamber 319. The exhausting portions 345 have an exhausting pump (not shown), and exhaust unreacted raw material gas, carrier gas, etc. to the outside of the growth chamber 319.

As shown in FIGS. 19 and 20, the extension nozzle 343 is disposed so as to be spaced from the upper surface of the susceptor 333 (the surface on which the tape-shaped base material T is disposed) at a predetermined interval h. The extension nozzle 343 guides the raw material gas jetted from the raw material gas jetting port 341a to the surface of the tape-shaped base material T as described above, whereby the amount of raw material gas contributing to the film formation of the tape-shaped base material T is increased and thus the raw material yield is enhanced. Accordingly, it is desirable from the viewpoint of increasing the raw material yield more greatly that the predetermined interval h is smaller to the extent that the running of the tape-shaped base material T is not disturbed. However, when the predetermined interval h is excessively small (the extension nozzle 343 and the susceptor 333 are excessively close to each other), the extension nozzle 343 is liable to be heated by radiation heat from the susceptor 333. In this case, the raw material gas passing through the extension nozzle 343 may react at a portion which has been heated by the radiation heat before the raw material gas reaches the tape-shaped base material T, which causes reduction in raw material yield. Therefore, the predetermined interval h between the extension nozzle and the susceptor 333 is desirable to be set to 10 mm or less.

The raw material gas flowing through the extension nozzle 343 is mainly discharged through the predetermined interval h between the second shielding plates 343b and the susceptor 333 to the exhausting portions 345. It has been found in this construction that unreacted raw material gas which does not contribute to the film formation is crystallized above the susceptor 333 at the outside of the support portion 333A in the width direction of the tape-shaped base material T and deposited on the susceptor 333 to form deposits (abnormal growth layer).

The deposit trend to grow as the time elapses, and when the ratio of the height of the deposit to the predetermined interval h between the extension nozzle 343 and the susceptor 333 increases, the value of the critical current value Ic of the manufactured superconductive wire rod decreases greatly, so that the superconductivity characteristic is deteriorated.

Therefore, in this embodiment, the susceptor 333 is provided with groove portions 338 (deposition avoiding portions) 338 which are located at both the sides of the support portion 333A in the width direction of the tape-shaped base material T so as to extend along the tape-shaped base material T, and the bottom surfaces of the groove portions 338 function as lower portions.

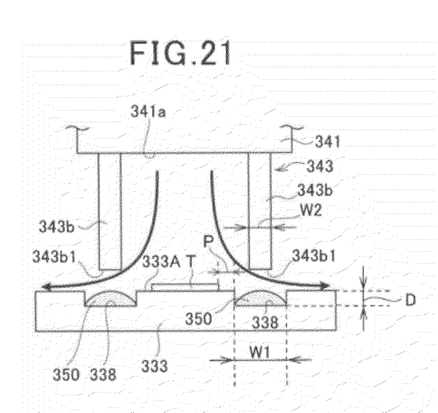

As shown in FIG. 21, the groove portions 338 are designed to be rectangular in cross-section, and formed just below the second shielding plates (passage walls) 343b of the extension nozzle 343. The areas just below the second shielding plates 343b are narrowest portions in the passage though which the raw material gas flows, and thus it has been found experimentally or the like that the raw material gas is liable to be decomposed and deposited when the raw material gas passes therethrough. Therefore, in this construction, the lower end portions (tips) 343b1 of the second shielding plates 343b of the extension nozzle 343 are formed just above the groove portions 338 (so as to face the areas within the widths of the groove portions 338), whereby formed deposits 350 can be accommodated in the groove portions 338. Accordingly, even when the deposit 350 grows to some extent, the gap between the deposit 350 and the lower end portion 343b1 of the second shielding plate 343b can be secured, and the flow of the raw material gas discharged to the outside through the gap can be prevented from being disturbed by the deposit 350.

Furthermore, the deposit 350 in the groove portion 338 can be suppressed from growing onto the tape-shaped base material T by depositing the deposit 350 in the groove portion 338. Accordingly, the deposit 350 can be prevented from disturbing the film formation of the superconductive layer, and the film formation of the superconductive layer onto the surface of the tape-shaped base material T can be stably performed.

The groove portion 338 is configured so that the width W1 thereof is larger than the thickness W2 of the lower end portion 343b1 of the second shielding plate 343b and the second shielding plate 343b is located within the width W1 of the groove portion 338. Furthermore, the groove portion 338 is formed so that the length in the running direction of the tape-shaped base material T is longer than at least the growth area L of the extension nozzle 343 as shown in FIG. 19. According to this construction, the second shielding plate 343b is disposed so as to face the groove portion 338, so that the distance between the lower end portion 343b1 of the second shielding plate 343b and the susceptor 333 can be prevented from being narrowed. Furthermore, the depth D of the groove portions 338 is set to be larger (for example, 2 mm) than the thickness of the tape-shaped base material T as shown in FIG. 21.

Furthermore, the support portion 333A is designed to be larger from both the edge portions in the width direction of the tape-shaped base material T by a predetermined interval P. The tape-shaped base material T may run while swinging (meandering) in the width direction during running. In this case, when the tape-shaped base material T runs in the groove portion 338, it may affect the film formation quality of the surface of the tape-shaped base material T. Therefore, the predetermined interval P is set to a value (1 to 2 mm in this embodiment) larger than an expected swinging amount in the width direction.

According to this embodiment, there are provided the raw material gas jetting unit 341 for jetting the raw material gas, the susceptor 333 for supporting the tape-shaped base material T and heating the tape-shaped base material T through heat transfer, the heater 335 for heating the susceptor 333, and the extension nozzle 343 for guiding the raw material gas jetted from the raw material gas jetting unit 341 to the surface of the tape-shaped base material T, the amount of the raw material gas contributing to the film formation of the tape-shaped base material T can be increased, and the raw material yield can be enhanced.

Furthermore, the susceptor 333 has the groove portions 338 which are located at both the sides of the support portion 333A for supporting the tape-shaped base material T so as to face the lower end portions 343b1 of the second shielding plates 343b of the extension nozzle 343 and lower in height than the support portion 333A, so that the formed deposits 350 can be accommodated in the groove portions 338. Accordingly, even when the deposits 350 grow to some extent, the interval between the deposits 350 and the lower end portions 343b1 of the second shielding plates 343b can be secured, and the flow of the raw material gas to be discharged to the outside through the gap can be prevented from being disturbed by the deposits 350.

Furthermore, the deposits 350 are deposited in the groove portions 338, whereby the deposits 350 in the groove portions 338 can be suppressed from growing onto the tape-shaped base material T. Accordingly, the deposits 350 can be prevented from disturbing the film formation of the superconductive layer, and the film formation of the superconductive layer onto the surface of the tape-shaped base material T can be stably performed.

Furthermore, according to this embodiment, the groove portions 338 are formed to be wider than the thickness W2 of the tips of the lower end portions 343b1 of the second shielding plates 343b of the extension nozzle 343. Therefore, the distance between the lower end portion 343b1 of the second shielding plate 343b and the susceptor 333 can be prevented from being narrowed, and the flow of the raw material gas between the second shielding plate 343b and the susceptor 333 can be prevented from being disturbed.

Next, a modification according to this embodiment will be described.

### [Third Modification]

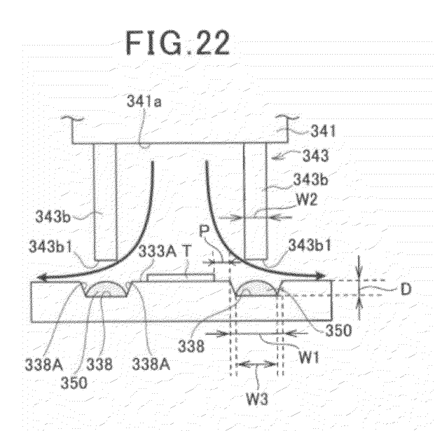

In the above embodiment, the groove portions 338 are configured to be rectangular in cross-section. However, this embodiment is not limited to this style, and the groove portions 338 may be formed to be substantially trapezoidal in cross-section so that the width W1 at the upper surface side is larger than the width W3 at the bottom surface side as shown in FIG. 22. Each groove portion 338 has a slope surface 338A which is inclined from the bottom surface to the upper surface. The other constructions are represented by the same reference numerals, and the description thereof is omitted.

According to this construction, the groove portions 338 can be simply designed to be wider than the thickness W2 of the tips of the lower end portions 343b1 of the second shielding plates 343b of the extension nozzle 343, and the raw material gas flows along each slope surface 338 A of the groove portions 338, thereby reducing the resistance to the flow of the raw material gas when the raw material gas flows through the gap between the lower end portion 343b1 of the second shielding plate 343b and the susceptor 333.

### [Modification 4]

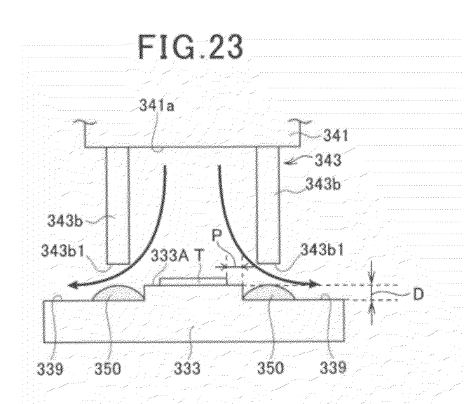

Furthermore, in the above embodiment, the groove portions 338 are formed in the susceptor 333. However, the present invention is not limited to this type, and lower portions 339 which are lower in height than the support portion 333A may be formed at both the sides in the width direction of the support portion 333A as shown in FIG. 23. The lower portions 339 are formed substantially at the same height from both the edges in the width direction of the support portion 333A to both the edges of the susceptor 333.

According to this construction, unevenness formed on the upper surface of the susceptor 333 can be suppressed, and the resistance to flow when the raw material gas flows through the gap between the lower end portion 343b1 of the second shielding plate 343b and the susceptor 333 can be further reduced.

### Fifth Embodiment

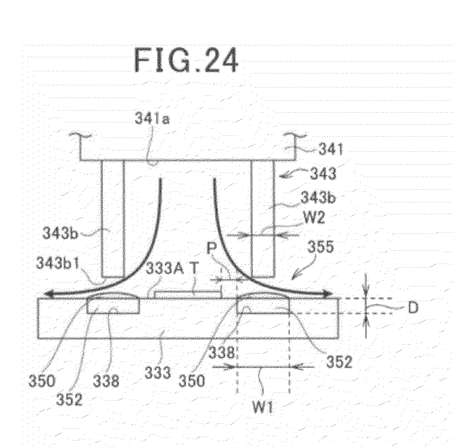

FIG. 24 is a partially cross-sectional view showing the internal construction of a growth chamber according to a fifth embodiment, and corresponds to FIG. 21.

In the fifth embodiment, the susceptor 333 is different in construction from the fourth embodiment in that cooling materials (low temperature members) 352 are disposed in the groove portions 338 formed at both the sides in the width direction of the support portion 333A. In this embodiment, the cooling members 352 function as low temperature portions (deposition avoiding portions) 355 which are lower in temperature than the support portion 333A. The other constituent elements are represented by the same references, and the description thereof is omitted.

The cooling members 352 are plate-like members, and they are designed in such shape and size that they are fitted in the groove portions 338. In this embodiment, the groove portions 338 are formed to be rectangular in cross-section, and thus the cooling members 352 are designed to have substantially the same shape as the groove portions 338.

The cooling members 352 are formed of material (for example, quartz, alumina or the like) which is smaller in thermal conductivity and larger in thermal emissivity than the metal material constituting the susceptor 333 (for example, SUS; stainless steel). Therefore, the heat of the susceptor 333 heated by the heater 335 (FIG. 20) is hardly transferred to the cooling members 352, and also heat is liable to be radiated from the cooling members 352, so that the temperature of the cooling members 352 can be kept to be lower than the susceptor 333.

According to an experiment, it has been found that the surface temperature of the cooling members 352 decreases by 50° C. or more as compared with the surface temperature of the support portion 333A of the susceptor 333 by disposing the cooling members 352 in the groove portions 338 confronting the lower end portions 343b1 of the second shielding plates 343b of the extension nozzle 343.

According to this embodiment, there are provided the raw material gas jetting unit 341 for jetting raw material gas, the susceptor 333 for supporting the tape-shaped base material T and heating the tape-shaped base material T through heat transfer, the heater 335 for heating the susceptor 333, and the extension nozzle 343 for guiding the raw material gas jetted from the raw material gas jetting unit 341 to the surface of the tape-shaped base material T, the amount of the raw material gas contributing to the film formation of the tape-shaped base material T can be increased, and the raw material yield can be enhanced.

Furthermore, the susceptor 333 has the groove portions 338 lower than the support portion 333A at both the sides of the support portion 333A for supporting the tape-shaped base material T so that the groove portions face the lower end portions 343b1 of the second shielding plates 343b of the extension nozzle 343, and the cooling members 352 which are lower in temperature than the support portion 333A are disposed in the groove portions 338. Therefore, the raw material gas can be suppressed from being thermally decomposed on the surfaces of the cooling members 352, and thus deposits 350 can be suppressed from being formed on the surfaces of the cooling members 352. Accordingly, the deposits deposited on the cooling members 352 can be suppressed from growing up on the tape-shaped base material T, so that the deposits can be prevented from disturbing the film formation of the superconductive layer, and the film formation of the superconductive layer on the surface of the tape-shaped base material T can be stably performed.

Furthermore, the cooling members 352 are formed of the material which is smaller in thermal conductivity than the material constituting the susceptor 333, and thus the surface temperature of the cooling members 352 can be kept to be lower than the surface temperature of the support portion 333A of the susceptor 333 with a simple construction.

Next, modifications of this embodiment will be described.

### [Modification 5]

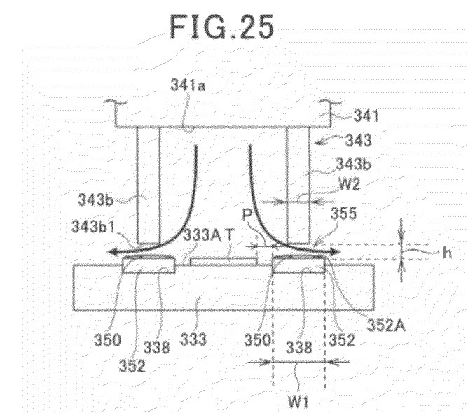

In the embodiment described above, the cooling members 352 disposed in the groove portions 338 are formed substantially at the same height as the support portion 333A of the susceptor 333, however, this embodiment is not limited to this style. The cooling members 352 may be disposed so that the upper surfaces 352A thereof protrude from the upper surface of the support portion 333A as shown in FIG. 25.

In this construction, the upper surfaces 352A of the cooling members 352 are set to be lower than the surface height of the tape-shaped base material T located on the support portion 333A. According to this arrangement, the cooling members 352 can be prevented from being higher than the tape-shaped base material T, and the raw material gas can be made to smoothly flow from the surface of the tape-shaped base material T to the upper surfaces 352A of the cooling members 352, so that the resistance to flow when the raw material gas flows through the gap between the lower end portion 343b1 of the second shielding plate 343b and the cooling member 352 can be reduced.

In this construction, it is desirable that the predetermined interval h between the lower end portion 343b1 of the second shielding plate 343b and the cooling member 352 is set to the same level as the embodiment described above.

### [Modification 6]

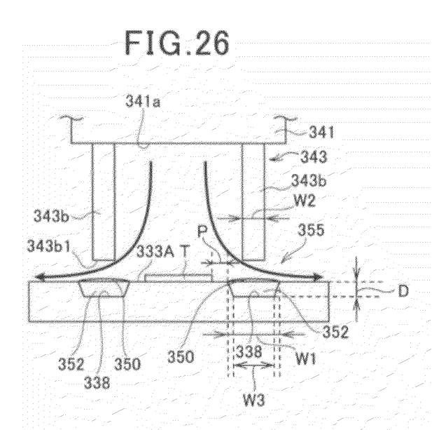

In this embodiment, the groove portions 338 are designed to be rectangular in cross-section. However, this embodiment is not limited to this style. Groove portions having trapezoidal cross-section in which the width W1 at the upper surface side is larger than the width W3 at the bottom surface side may be formed and cooling members 352 having substantially the same shape as the groove portions 338 may be arranged in the groove portions as shown in FIG. 26.

In this construction, as compared with the construction of the above embodiment, the area of the region whose temperature is lower on the surface of the susceptor 333 can be enlarged, and thus formation of deposits on the surface of the susceptor 333 can be more remarkably suppressed.

### [Modification 7]

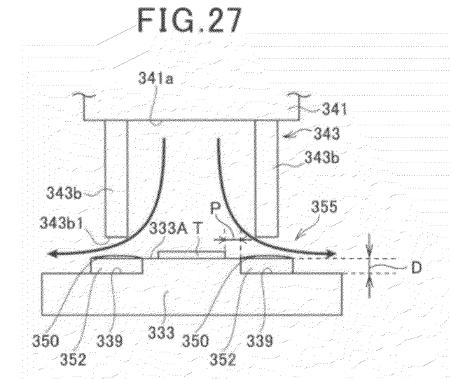

Furthermore, in this embodiment, the groove portions 338 are formed in the susceptor 333. However, this embodiment is not limited to this style. As shown in FIG. 27, lower portions (deposit avoiding portions) which are lower than the support portion 333A may be formed at both the sides in the width direction of the support portion 333A, and the cooling members 352 may be arranged on the lower portions 339. The lower portions 339 are formed substantially at the same height from both the edges in the width direction of the support portion 33A to both the edges of the susceptor 333.

According to this construction, it is unnecessary to fit the shape of the cooling members 352 to the shape of the groove portions 338. Therefore, the degree of freedom of the shape of the cooling members 352 can be enhanced, and the cooling members 352 can be easily molded. In this construction, the upper surfaces 352A of the cooling members 352 may be protruded from the support portion 333A to the extent that the upper surfaces 352A are lower than the surface (upper surface) of the tape-shaped base material T as in the case of the modification 5.

### Sixth Embodiment

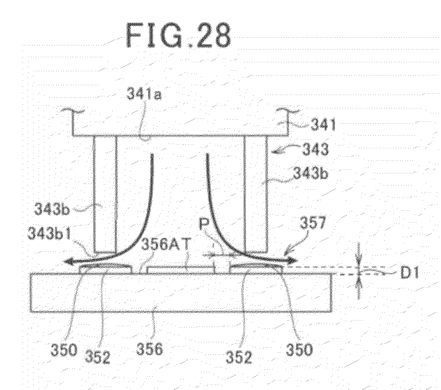

FIG. 28 is a partially cross-sectional view showing the internal construction of a growth chamber according to a sixth embodiment, and corresponds to FIG. 21.

In the fifth embodiment, as shown in FIGS. 24 to 27, the susceptor 333 have the groove portions 338 (the low portions 339) at both the sides in the width direction of the support portion 333A, and the cooling members 352 are arranged in the groove portions 338 (the low portions 339), however, this embodiment is not limited to this style. A flat plate type susceptor 356 may be provided, and the cooling members 352 may be arranged at both the sides in the width direction of the support portion 356A for supporting the tape-shaped base material T.

The cooling members 352 are spaced from the tape-shaped base material T at a predetermined interval P, and arranged substantially at the same height as the support portion 356A. The thickness D1 of the cooling members 352 are set to be smaller than the thickness of the tape-shaped base material T. In this embodiment, the cooling members 352 function as the low temperature portions 357. The other constituent elements are represented by the same reference numerals, and the description thereof is omitted.

In this embodiment, the susceptor 356 has the cooling members 352 which are lower in temperature than the support portion 356A and located at both the sides of the support portion 356A for supporting the tape-shaped based material T so as to face the lower end portions 343b1 of the second shielding plates 343b of the extension nozzle 343. Therefore, the raw material gas can be suppressed from being thermally decomposed on the surfaces of the cooling members 352, and formation of deposits 350 on the surfaces of the cooling members 352 can be suppressed. Accordingly, deposits deposited on the cooling members 352 can be suppressed from growing up onto the tape-shaped base material T. Therefore, the deposits can be prevented from disturbing the film formation of the superconductive layer, and the film formation of the superconductive layer on the surface of the tape-shaped base material T can be stably performed.

Furthermore, in this embodiment, it is unnecessary to provide the groove portions to the support portion 356A in the susceptor 356, the construction of the susceptor 356 can be simplified, and the cooling members 352 can be simply arranged.

The present invention is described specifically on the basis of the embodiments. However, the present invention is not limited to the embodiments, and the embodiments may be modified without departing from the subject of the present invention.

For example, in the above embodiment, one tape-shaped base material T reciprocates in the growth chamber 319, however, the present invention is not limited to this style. A multi-turn system in which the tape-shaped base material T turns around at plural times in the growth chamber 319 may be used. In this construction, the low portions or the low temperature portions are formed at both the sides of the support portion for supporting the tape-shaped base material T juxtaposed in the growth chamber.

The embodiments disclosed in this application are exemplary embodiments of the present invention, and do not limit the present invention. It is intended that the scope of the present invention is defined not by the description of the specification, but by the following claims, and all modifications associated with equivalents to the claims are contained.

What is claimed is:

1. A CVD apparatus comprising:
a raw material gas jetting portion that jets raw material gas;
a susceptor that supports a tape-shaped base material and heats the tape-shaped base material through heat transfer;
a heater that heats the susceptor;
an inert gas introducing portion that introduces inert gas to suppress contact between the heater and the raw material gas; and
a raw material gas transport passage that guides the raw material gas jetted from the raw material gas jetting portion to the surface of the tape-shaped base material.

2. The CVD apparatus according to claim 1, wherein the raw material gas transport passage is disposed so as to be spaced from the susceptor at a predetermined interval.

3. The CVD apparatus according to claim 1, wherein the raw material gas transport passage has an open end narrower than the width of the susceptor, and is disposed along a running area of the tape-shaped base material formed at a center in the width direction of the susceptor.

4. The CVD apparatus according to claim 3, wherein an interval distance between the raw material gas transport passage and the susceptor is smaller than the width of the open end of the raw material gas transport passage.

5. The CVD apparatus according to claim 1, wherein the reaction chamber is provided with a temperature controller that controls the temperature of raw material gas passing through the raw material gas transport passage.

6. The CVD apparatus according to claim 1, wherein the susceptor is provided with a support portion that supports the tape-shaped base material, and dummy tapes are disposed at both the sides of the support portion.

7. The CVD apparatus according to claim 6, wherein the raw material gas transport passage is disposed so as to be spaced from the susceptor at a predetermined interval, and the tip of a passage wall of the raw material gas transport passage is disposed so as to face an area within the width of the dummy tapes.

8. The CVD apparatus according to claim 6, wherein the dummy tapes are disposed so as to protrude from an end portion of a passage wall of the raw material gas transport passage to the opposite side to the tape-shaped base material in the width direction of the dummy tapes.

9. The CVD apparatus according to claim 6, wherein the dummy tapes are disposed so as to be spaced from both the edge portions in the width direction of the tape-shaped base material at predetermined intervals.

10. The CVD apparatus according to claim 6, wherein the tape-shaped base material is suspended between and wound around a pair of reels, and the dummy tapes are suspended between and wound around a pair of dummy tape reels disposed at the outside of the reels in the suspending and winding direction of the tape-shaped base material.

11. The CVD apparatus according to claim 1, wherein the susceptor is provided with lower portions that are lower in height than the support portion and located at both the sides of the support portion for supporting the tape-shaped base material so as to face the tip of a passage wall of the raw material gas transport passage.

12. The CVD apparatus according to claim 11, wherein the lower portions are configured to be wider than the thickness of the tip of the passage wall of the raw material gas transport passage.

13. The CVD apparatus according to claim 11, wherein the susceptor has a pair of groove portions extending along the tape-shaped base material at both the sides of the support portion, and the lower portions contain at least bottom surfaces of the groove portions.

14. The CVD apparatus according to claim 11, wherein low temperature members that are lower in temperature than the susceptor are arranged at the lower portions.

15. The CVD apparatus according to claim 14, wherein the low temperature members are formed of material that is smaller in thermal conductivity than material constituting the susceptor.

16. The CVD apparatus according to claim 14, wherein the height positions of the surfaces of the low temperature members are set to be lower than the height position of the surface of the tape-shaped base material supported on the support portion.

17. The CVD apparatus according to claim 1, wherein the susceptor is provided with low temperature portions that are lower in temperature than the support portion and located at both the sides of the support portion for supporting the tape-shaped base material so as to face the tip of the passage wall of the raw material gas passage.

18. The CVD apparatus according to claim 17, wherein low temperature members that are lower in temperature than the susceptor are arranged at the low temperature portions.

19. The CVD apparatus according to claim 17, wherein the low temperature members are formed of material which is smaller in thermal conductivity than material constituting the susceptor.

20. The CVD apparatus according to claim 17, wherein the height positions of the surfaces of the low temperature members are set to be lower than the height position of the surface of the tape-shaped base material supported on the support portion.
